(19) United States
(12) Patent Application Publication
(10) Pub. No.: US 2025/0057016 A1
(43) Pub. Date: Feb. 13, 2025

(54) DISPLAY DEVICE AND ELECTRONIC DEVICE

(71) Applicant: SONY SEMICONDUCTOR SOLUTIONS CORPORATION, KANAGAWA (JP)

(72) Inventor: MASASHI UCHIDA, KANAGAWA (JP)

(21) Appl. No.: 18/718,295

(22) PCT Filed: Nov. 15, 2022
(86) PCT No.: PCT/JP2022/042411

§ 371 Date: Jun. 10, 2024

(30) Foreign Application Priority Data
Dec. 17, 2021 (JP) 2021-205519

(51) Int. Cl. H10K 59/80; H10K 59/122; H10K 59/38; H10K 102/00

(52) U.S. Cl. CPC H10K 59/876; H10K 59/122; H10K 59/38; H10K 59/879; H10K 2102/3026

(57) ABSTRACT

Provided is a display device capable of collecting light on an own pixel. A display device includes a plurality of light emitting elements arranged two-dimensionally and a plurality of reflective structures provided individually above the plurality of light emitting elements. The light emitting element includes an organic layer including a light emitting layer. The reflective structure includes a first reflective layer having a concave shape concaved in a direction away from the light emitting element, and having an opening in a bottom portion of the concave shape, and a reflector provided between the opening and the light emitting element.

### TECHNICAL FIELD

The present disclosure relates to a display device and an electronic device including the display device.

### BACKGROUND ART

Light emitting devices in which a plurality of organic light emitting diode (OLED) elements is two-dimensionally arranged are widely used. In this light emitting device, light output from an OLED element to a wide-angle side enters an adjacent pixel as stray light, and color purity decreases and luminous efficiency decreases. For this reason, a technique of using a structure capable of collecting light on an own pixel to suppress stray light to an adjacent pixel and improving color purity and luminous efficiency has been studied.

Patent Document 1 discloses a structure in which light emitted by an organic electroluminescence layer is guided between a first electrode and a second electrode, and extracted from a light transmission unit of the second electrode to a front surface.

### CITATION LIST

### Patent Document

Patent Document 1: Japanese Patent Application Laid-Open No. 2015-109190

### SUMMARY OF THE INVENTION

### Problems to be Solved by the Invention

As described above, in recent years, a light emitting device capable of collecting light on an own pixel has been desired.

An object of the present disclosure is to provide a display device capable of collecting light on an own pixel and an electronic device including the display device.

### Solutions to Problems

In order to solve the problem described above, a display device according to the present disclosure includes:
a plurality of light emitting elements arranged two-dimensionally; and
a plurality of reflective structures provided individually above a plurality of the light emitting elements, in which
each of the light emitting elements includes an organic layer including a light emitting layer, and
each of the reflective structures includes:
a first reflective layer having a concave shape concaved in a direction away from each of the light emitting elements and having an opening at a bottom portion of the concave shape; and
a reflector provided between the opening and each of the light emitting elements.

The display device according to the present disclosure may be provided in an electronic device.

### BRIEF DESCRIPTION OF DRAWINGS

FIG. 1 is a plan view illustrating an example of a configuration of a display device according to one embodiment.

FIG. 2 is an enlarged plan view illustrating a part of a display region of the display device according to one embodiment.

FIG. 3 is a cross-sectional view taken along line III-III of FIG. 2.

FIGS. 4A, 4B, and 4C are each a process diagram for explaining an example of a method for manufacturing the display device according to one embodiment.

FIGS. 5A, 5B, and 5C are each a process diagram for explaining an example of the method for manufacturing the display device according to one embodiment.

FIGS. 6A, 6B, and 6C are each a process diagram for explaining an example of the method for manufacturing the display device according to one embodiment.

FIGS. 7A, 7B, and 7C are each a process diagram for explaining an example of the method for manufacturing the display device according to one embodiment.

FIG. 8 is a cross-sectional view illustrating an example of a configuration of a display device according to Modification 1.

FIGS. 9A, 9B, and 9C are each a process diagram for explaining an example of a method for manufacturing the display device according to Modification 1.

FIGS. 10A 10B, 10C, and 11D are each a process diagram for explaining an example of the method for manufacturing the display device according to Modification 1.

FIG. 11 is a cross-sectional view illustrating an example of a configuration of a display device according to Modification 2.

FIGS. 12A and 12B are each a process diagram for explaining an example of a method for manufacturing the display device according to Modification 2.

FIGS. 13A and 13B are each a process diagram for explaining an example of the method for manufacturing the display device according to Modification 2.

FIG. 14 is a cross-sectional view illustrating an example of a configuration of a display device according to Modification 3.

FIG. 15 is a cross-sectional view illustrating an example of a configuration of a display device according to Modification 4.

FIG. 16 is a cross-sectional view illustrating an example of a configuration of a display device according to Modification 5.

FIG. 17 is a cross-sectional view illustrating an example of a configuration of a display device according to Modification 6.

FIG. 18 is a cross-sectional view illustrating an example of a configuration of the display device according to Modification 6.

FIG. 19 is a cross-sectional view illustrating an example of a configuration of a display device according to Modification 7.

FIG. 20 is a cross-sectional view illustrating an example of a configuration of a display device according to Modification 8.

FIG. 21 is a cross-sectional view illustrating an example of a configuration of a display device according to Modification 9.

FIG. 22 is a cross-sectional view illustrating an example of a configuration of a display device according to Modification 10.

FIG. 23 is a cross-sectional view illustrating an example of a configuration of the display device according to Modification 10.

FIG. 24 is a cross-sectional view illustrating an example of a configuration of a display device according to Modification 11.

FIG. 25 is a cross-sectional view illustrating an example of a configuration of a display device according to Modification 12.

FIG. 26 is a cross-sectional view illustrating an example of a configuration of a display device according to Modification 13.

FIG. 27 is a cross-sectional view illustrating an example of a configuration of a display device according to Modification 14.

FIG. 28 is a cross-sectional view illustrating an example of a configuration of a display device according to Modification 15.

FIG. 29 is a cross-sectional view illustrating an example of a configuration of a display device according to Modification 16.

FIG. 30 is a cross-sectional view illustrating an example of a configuration of a display device according to Modification 17.

FIG. 31 is an enlarged plan view illustrating a part of a display region of a display device according to Modification 18.

FIG. 32A is an enlarged plan view illustrating a part of a display region of a display device according to Modification 19.

FIG. 32B is an enlarged plan view illustrating a part of a display region of a display device according to Modification 20.

FIG. 33A is an enlarged plan view illustrating a part of a display region of a display device according to Modification 21.

FIG. 33B is an enlarged plan view illustrating a part of a display region of a display device according to Modification 22.

FIG. 34A is an enlarged plan view illustrating a part of a display region of a display device according to Modification 23.

FIG. 34B is an enlarged plan view illustrating a part of a display region of a display device according to Modification 24.

FIG. 35A is a front view illustrating an example of an appearance of a digital still camera. FIG. 35B is a rear view illustrating an example of an appearance of the digital still camera.

FIG. 36 is a perspective view of an example of an appearance of a head mounted display.

FIG. 37 is a perspective view illustrating an example of an appearance of a television device.

### MODE FOR CARRYING OUT THE INVENTION

An embodiment of the present disclosure will be described in the following order with reference to the drawings. Note that, in all the drawings of the following embodiments, the same or corresponding parts are denoted by the same reference numerals.
1 One embodiment (example of display device)
2 Modification (modification of display device)
3 Application example (example of electronic device)

### 1 One Embodiment

### [Configuration of Display Device 10]

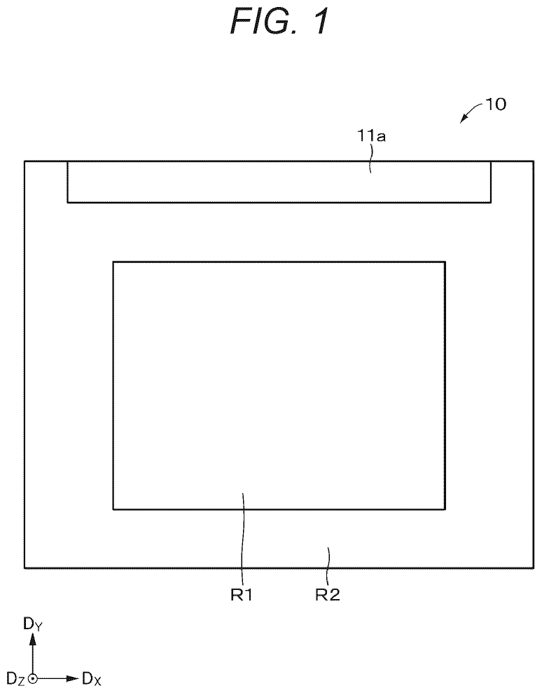

FIG. 1 is a plan view illustrating an example of a configuration of a display device 10 according to one embodiment. The display device 10 includes a display region R1 and a peripheral region R2 provided around the display region R1. The display region R1 has a rectangular shape in plan view. In the present specification, plan view means plan view when a target object is viewed from a direction D_{Z} (hereinafter, referred to as a “front direction D_{Z}”) perpendicular to a display surface of the display device 10 unless otherwise specified. In the present specification, a direction parallel to a long side of the display region R1 is referred to as a horizontal direction D_{X}, and a direction parallel to a short side of the display region R1 is referred to as a vertical direction D_{Y}.

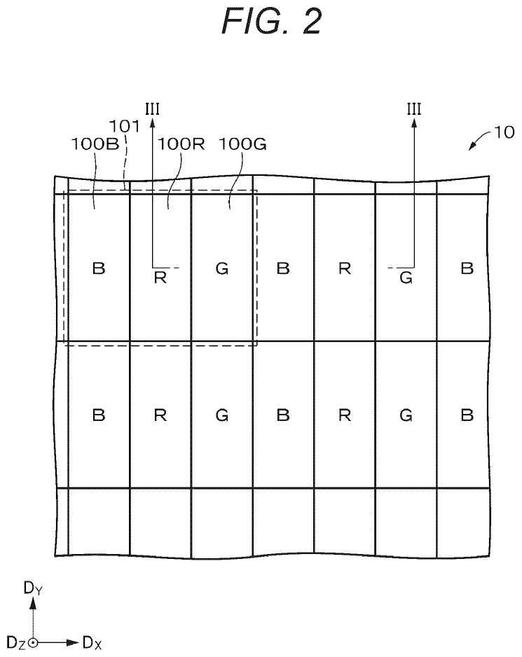

FIG. 2 is an enlarged plan view illustrating a part of the display region R1 of the display device 10 according to one embodiment. A plurality of subpixels 100R, 100G, and 100B is two-dimensionally arranged in a prescribed arrangement pattern in the display region R1. Note that FIG. 2 illustrates an example in which the prescribed arrangement pattern is a stripe arrangement. In the peripheral region R2, a pad 11a, a driver (not illustrated) for video display, and the like are provided. A flexible printed circuit (FPC) (not illustrated) may be connected to the pad 11a.

The subpixels 100R can emit red light. The subpixels 100G can emit green light. The subpixels 100B can emit blue light. Red is an example of a first primary color among the three primary colors. Green is an example of a second primary color among the three primary colors. Blue is an example of a third primary color among the three primary colors. In FIG. 2, sections denoted by symbols “R”, “G”, and “B” represent the subpixel 100R, the subpixel 100G, and the subpixel 100B, respectively.

In the following description, when collectively referred to without being distinguished from one another, the subpixels 100R, 100G, and 100B will be referred to as subpixels 100. One pixel 101 includes three subpixels 100R, 100G, and 100B adjacent to each other in the horizontal direction D_{X}.

The subpixels 100R, 100G, and 100B have, for example, a rectangular shape in plan view. In the present specification, the rectangular shape also includes a square shape. Note that FIG. 2 illustrates an example in which the subpixels 100R, 100G, and 100B each have a rectangular shape having short sides parallel to the horizontal direction D_{X} and long sides parallel to the vertical direction D_{Y}.

The display device 10 is an example of a light emitting device. The display device 10 is a top emission type OLED display device. The display device 10 may be a microdisplay. The display device 10 may be provided in a virtual reality (VR) device, a mixed reality (MR) device, an augmented reality (AR) device, an electronic view finder (EVF), a small projector, or the like.

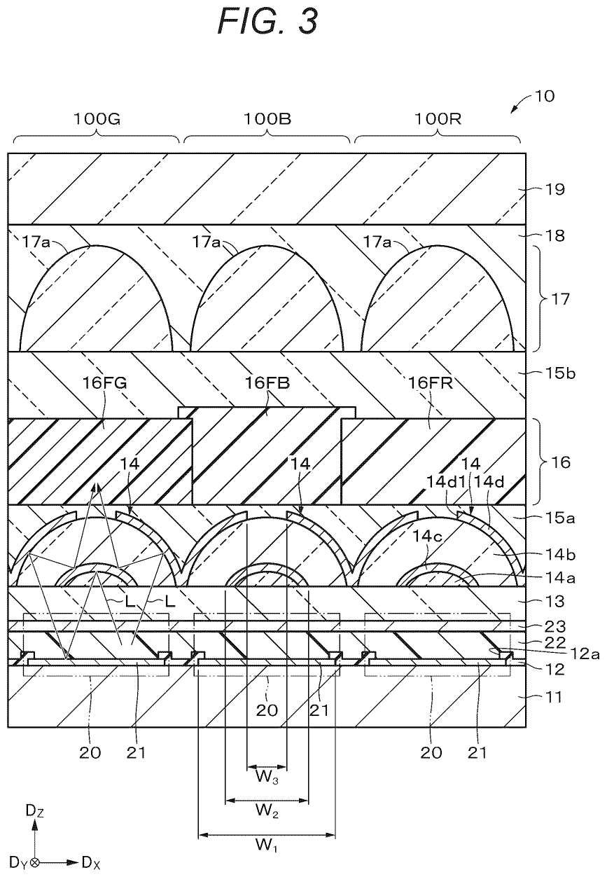

FIG. 3 is a cross-sectional view taken along line III-III of FIG. 2. The display device 10 includes a circuit board 11, a plurality of light emitting elements 20, an insulating layer 12, a protective layer 13, a plurality of reflective structures 14, a planarization layer 15a, a color filter 16, a planarization layer 15b, a lens array 17, a filling resin layer 18, and a counter substrate 19. A combination of the color filter 16 and the light emitting element 20 constitutes the plurality of subpixels 100R, 100G, and 100B.

In the following description, in each layer constituting the display device 10, a surface on the top side (display surface side) of the display device 10 is referred to as first surface, and a surface on the bottom side (side opposite to the display surface) of the display device 10 is referred to as second surface.

### (Circuit Board 11)

The circuit board 11 is what is called a backplane, and drives the plurality of light emitting elements 20. The circuit board 11 includes a substrate. A plurality of wiring lines, a drive circuit that drives the plurality of light emitting elements 20, a power supply circuit that supplies power to the plurality of light emitting elements 20, and the like (all not illustrated) are provided on the first surface of the substrate. The insulating layer covers the first surface of the substrate and planarizes the first surface of the substrate.

The substrate may be configured by, for example, a semiconductor easily formed with a transistor or the like, or may be configured by glass or resin having low moisture and oxygen permeability. Specifically, the substrate may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

### (Light Emitting Element 20)

The light emitting element 20 is a white OLED element, and can emit white light under the control of the drive circuit and the like. The white OLED elements may be white micro-OLED (MOLED) elements. The plurality of light emitting elements 20 is two-dimensionally arranged on the first surface of the circuit board 11 in a prescribed arrangement pattern. The light emitting element 20 includes a first electrode 21, an OLED layer 22, and a second electrode 23 sequentially on the first surface of the circuit board 11.

### (First Electrode 21)

The first electrode 21 is an example of a second reflective layer that reflects light emitted from the OLED layer 22. The first electrode 21 is an anode. When a voltage is applied between the first electrode 21 and the second electrode 23, holes are injected from the first electrode 21 into the OLED layer 22. The first electrode 21 has a planar shape perpendicular to a thickness direction of the light emitting element 20. The first electrode 21 is divided between adjacent light emitting elements 20, and is separately provided for the plurality of light emitting elements 20. The plurality of first electrodes 21 is two-dimensionally arranged on the first surface of the circuit board 11 in an arrangement pattern similar to the arrangement pattern of the plurality of light emitting elements 20.

The first electrode 21 may be formed by, for example, a metal layer also serving as a reflective layer, or may be formed by a metal layer and a transparent conductive oxide layer. In a case where the first electrode 21 includes a metal layer and a transparent conductive oxide layer, the transparent conductive oxide layer is preferably provided adjacent to the OLED layer 22 side from the viewpoint of placing a layer having a high work function adjacent to the OLED layer 22.

The metal layer also has a function as a reflective layer that reflects light emitted from the OLED layer 22. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

A base layer (not illustrated) may be provided adjacent to the second surface side of the metal layer. The base layer can improve crystal orientation of the metal layer at the time of forming the metal layer. The base layer includes, for example, at least one metal element selected from a group including titanium (Ti) and tantalum (Ta). The base layer may include the at least one metal element described above as a constituent element of an alloy.

The transparent conductive oxide layer includes a transparent conductive oxide. The transparent conductive oxide includes, for example, at least one selected from a group including a transparent conductive oxide including indium (hereinafter referred to as “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among these transparent conductive oxides, the indium tin oxide (ITO) is particularly preferable. This is because the indium tin oxide (ITO) has a particularly low barrier for hole injection into the OLED layer 22 in terms of a work function, so that the drive voltage of the display device 10 can be particularly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (OLED Layer 22)

The OLED layer 22 is an example of an organic layer including a light emitting layer. The OLED layer 22 can emit white light by recombination of holes injected from the first electrode 21 and electrons injected from the second electrode 23.

The OLED layer 22 is provided on the plurality of first electrodes 21. The OLED layer 22 is connected between adjacent light emitting elements 20 in the display region R1, and is shared by the plurality of light emitting elements 20 in the display region R1.

The OLED layer 22 may be an OLED layer including a single-layer light emitting unit, an OLED layer including a two-layer light emitting unit (tandem structure), or an OLED layer having a structure other than these units. The OLED layer including a single-layer light emitting unit has, for example, a configuration in which a hole injection layer, a hole transport layer, a red light emitting layer, a light emitting separation layer, a blue light emitting layer, a green light emitting layer, an electron transport layer, and an electron injection layer are stacked in this order from the first electrodes 21 toward the second electrode 23. The OLED layer including a two-layer light emitting unit has, for example, a configuration in which a hole injection layer, a hole transport layer, a blue light emitting layer, an electron transport layer, a charge generation layer, a hole transport layer, a yellow light emitting layer, an electron transport layer, and an electron injection layer are stacked in this order from the first electrodes 21 toward the second electrode 23.

The hole injection layer can enhance efficiency of hole injection into each light emitting layer and suppress leakage. The hole transport layer can enhance efficiency of hole transport to each light emitting layer. The electron injection layer can enhance efficiency of electron injection into each light emitting layer. The electron transport layer can enhance efficiency of electron transport to each light emitting layer. The light emitting separation layer is a layer that can adjust injection of carriers into each light emitting layer, and light emission balance of each color is adjusted by injecting electrons or holes into each light emitting layer via the light emitting separation layer. The charge generation layer can individually supply electrons and holes to two light emitting layers sandwiching the charge generation layer.

In response to application with an electric field to each of the red light emitting layer, the green light emitting layer, the blue light emitting layer, and the yellow light emitting layer, recombination occurs between holes injected from the first electrode 21 or the charge generation layer and electrons injected from the second electrode 23 or the charge generation layer, and red light, green light, blue light, and yellow light can be emitted.

### (Second Electrode 23)

The second electrode 23 is a cathode. When a voltage is applied between the first electrode 21 and the second electrode 23, electrons are injected from the second electrode 23 into the OLED layer 22. The second electrode 23 is a transparent electrode having transparency to visible light. In the present specification, visible light refers to light in a wavelength range of from 360 nm or more to 830 nm. The second electrode 23 is provided on the first surface of the OLED layer 22. The second electrode 23 is connected between adjacent light emitting elements 20 in the display region R1, and is shared by the plurality of light emitting elements 20 in the display region R1.

The second electrode 23 preferably includes a material having as high transmissivity as possible and a small work function, in order to enhance luminous efficiency. The second electrode 23 includes, for example, at least one of a metal layer or a transparent conductive oxide layer. More specifically, the second electrode 23 includes a single layer film of a metal layer or a transparent conductive oxide layer, or a laminated film of the metal layer and the transparent conductive oxide layer. In a case where the second electrode 23 is constituted by a stacked film, the metal layer may be provided on the OLED layer 22 side, or the transparent conductive oxide layer may be provided on the OLED layer 22 side, but from the viewpoint of allowing a layer having a low work function to adjoin the OLED layer 22, the metal layer is preferably provided on the OLED layer 22 side.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include a MgAg alloy, a MgAl alloy, an AlLi alloy, and the like. The transparent conductive oxide layer includes a transparent conductive oxide. As the transparent conductive oxide, a material similar to the transparent conductive oxide of the first electrode 21 described above can be exemplified.

### (Insulating Layer 12)

The insulating layer 12 insulates between adjacent first electrodes 21. The insulating layer 12 is provided in a portion between the separated first electrodes 21 on the first surface of the circuit board 11. The insulating layer 12 has a plurality of openings 12a. Each of the plurality of openings 12a is provided for a corresponding one of the light emitting elements 20. Specifically, each of the plurality of openings 12a is provided on the first surface (a surface on the OLED layer 22 side) of each first electrode 21. The first electrodes 21 and the OLED layer 22 are in contact with each other via the openings 12a.

The insulating layer 12 may be an organic insulating layer, an inorganic insulating layer, or a laminate of the organic insulating layer and the inorganic insulating layer. The organic insulating layer includes, for example, at least one selected from a group including a polyimide-based resin, an acrylic resin, a novolac-based resin, and the like. The inorganic insulating layer includes, for example, at least one selected from a group including silicon oxide (SiOx), silicon nitride (SiNx), silicon oxynitride (SiOxNy), and the like.

### (Protective Layer 13)

The protective layer 13 has transparency to visible light. The protective layer 13 is provided on the first surface of the second electrode 23 and covers the plurality of light emitting elements 20. The protective layer 13 can suppress moisture infiltration into the light emitting element 20 from an external environment. Furthermore, in a case where the second electrode 23 includes a metal layer, the protective layer 13 can suppress oxidation of the metal layer.

The protective layer 13 contains, for example, an inorganic material or a polymer resin each having low hygroscopicity. The protective layer 13 may have a single layer structure or a multilayer structure. In a case where the thickness of the protective layer 13 is increased, a multilayer structure is preferable. This is for alleviating the internal stress in the protective layer 13. The inorganic material includes, for example, at least one selected from a group including silicon oxide (SiOx), silicon nitride (SiNx), silicon oxynitride (SiOxNy), titanium oxide (TiOx), aluminum oxide (AlOx), and the like. The polymer resin includes, for example, at least one selected from a group including a thermosetting resin, an ultraviolet curable resin, and the like. Specifically, the polymer resin includes, for example, at least one selected from the group from an acrylic resin, a polyimide resin, a novolac resin, an epoxy resin, a norbornene resin, and the like.

The protective layer 13 may include a metal oxide layer. The metal oxide layer preferably contains a deposit of a monolayer. When the metal oxide layer contains a deposit of a monolayer, the effect of suppressing moisture infiltration by the protective layer 13 can be improved. The metal oxide layer may be included inside the protective layer 13 or may constitute the first surface of the protective layer 13. The metal oxide layer contains, for example, aluminum oxide (AlOx) or titanium oxide (TiOx).

### (Reflective Structure 14)

The reflective structure 14 can collect light L output from the light emitting element 20 to the wide-angle side, in the front direction D_{Z} by reflection. The plurality of reflective structures 14 is two-dimensionally arranged on the first surface of the protective layer 13 in a prescribed arrangement pattern similar to that of the plurality of light emitting elements 20. Each reflective structure 14 is provided above the light emitting element 20. A center axis of the reflective structure 14 and a center axis of the light emitting element 20 preferably substantially coincide with each other. In the display device 10 according to one embodiment, a center axis of the first electrode 21 is the center axis of the light emitting element 20. In the present specification, a center axis of the constituent members (for example, the light emitting element 20, the reflective structure 14, and the like) of the display device 10 represents an axis that passes through a geometric center of the constituent members of the display device 10 in plan view and is parallel to the front direction D_{Z}. The reflective structure 14 sequentially includes a structure 14a, a reflective layer 14c, a structure 14b, and a reflective layer 14d.

### (Structure 14a)

The structure 14a has transparency to visible light. As a result, the light L incident on the structure 14a can be transmitted, and reflected by the second surface of the reflective layer 14c. The structure 14a has a convex surface protruding in a direction away from the light emitting element 20. The convex surface is, for example, a convex curved surface or a frustum surface. The convex curved surface has, for example, a dome shape. The convex curved surface having a dome shape is, for example, a substantially parabolic surface, a substantially hemispherical surface, a substantially semielliptical surface, or the like. The frustum surface is, for example, a substantially truncated cone surface, a substantially elliptical frustum surface, or a substantially truncated pyramid surface. The substantially truncated pyramid surface is, for example, a substantially quadrangular truncated pyramid surface or a substantially hexagonal truncated pyramid surface. Adjacent structures 14a are separated from each other. A flat portion is provided between the adjacent structures 14a.

A plurality of the structures 14a is two-dimensionally arranged on the first surface of the protective layer 13 in a prescribed arrangement pattern similar to that of the plurality of light emitting elements 20. A center axis of the structure 14a and the center axis of the light emitting element 20 may substantially coincide with each other.

The structure 14a contains, for example, an inorganic material or a polymer resin. The inorganic material and the polymer resin may be known lens materials used for on-chip microlenses (OCL) and the like. The inorganic material contains, for example, silicon oxide (SiOx). The polymer resin includes, for example, an acrylic resin. The structure 14a may contain an ultraviolet curable resin.

### (Reflective Layer 14c)

The reflective layer 14c is an example of a reflector. The reflective layer 14c reflects, on the second surface, the light L output from the light emitting element 20 and the light L reflected by the first electrode 21. The reflective layer 14c reflects the light L reflected by the reflective layer 14d on the first surface. The reflective layer 14c is provided on the convex surface of the structure 14a and follows the convex surface. The reflective layer 14c has a concave surface shape concaved in a direction away from the light emitting element 20. The concave surface shape is a shape similar to that of the convex surface of the structure 14a. The concave surface shape has, for example, a concave curved surface shape or a frustum surface shape. The concave curved surface shape is, for example, a substantially parabolic shape, a substantially hemispherical shape, a substantially semielliptical shape, or the like. The frustum surface shape is, for example, a substantially truncated cone surface shape, a substantially elliptical frustum surface shape, or a substantially truncated pyramid surface shape. The substantially truncated pyramid shape is, for example, a substantially quadrangular truncated pyramid surface shape or a substantially hexagonal truncated pyramid surface shape. A center axis of the reflective layer 14c and the center axis of the light emitting element 20 may substantially coincide with each other.

The reflective layer 14c contains, for example, metal. The metal includes, for example, at least one type selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The reflective layer 14c may contain the at least one type of metal described above as a constituent element of alloy. Specific examples of the alloy include an aluminum alloy and a silver alloy.

### (Structure 14b)

The structure 14b separates the reflective layer 14c and the reflective layer 14d from each other. The structure 14b has transparency to visible light. As a result, the light L incident on the structure 14b can be reflected between the reflective layer 14c and the reflective layer 14c. The structure 14b has a convex surface protruding in a direction away from the light emitting element 20. The convex surface is, for example, for example, a convex curved surface or a frustum surface. As the shapes of the convex curved surface and the frustum surface, shapes similar to those of the convex curved surface and the frustum surface of the structure 14a can be exemplified. A center axis of the structure 14b and the center axis of the light emitting element 20 may substantially coincide with each other. The center axis of the structure 14b and the center axis of the structure 14a may substantially coincide with each other.

The structure 14b has a concave portion concaved in a direction away from the light emitting element 20, at a central portion of a bottom surface. The structure 14a in which the reflective layer 14c is provided on the convex surface is provided in the concave portion. The concave portion has a shape similar to that of the reflective layer 14c, and the concave surface of the concave portion and the convex surface of the reflective layer 14c are in close contact with each other.

As a material of the structure 14b, a material similar to that of the structure 14a can be exemplified. The structure 14a and the structure 14b may contain the same material or different materials.

### (Reflective Layer 14d)

The reflective layer 14d is an example of a first reflective layer. The reflective layer 14d reflects, on the second surface, the light L output from the light emitting element 20, the light L reflected by the first electrode 21, and the light L reflected by the reflective layer 14c. The reflective layer 14d has a concave surface shape concaved in a direction away from the light emitting element 20. The reflective layer 14d is provided on the convex surface of the structure 14b and follows the convex surface. The reflective layer 14d is connected between adjacent reflective structures 14 in the display region R1, and is shared by the plurality of reflective structures 14 in the display region R1. However, the reflective layer 14d may be divided between the adjacent reflective structures 14 in the display region R1.

The concave surface shape is a shape substantially similar to that of the convex surface of the structure 14a. As the concave surface shape, a shape similar to that of the concave surface of the reflective layer 14c can be exemplified. A center axis of the reflective layer 14d and the center axis of the light emitting element 20 may substantially coincide with each other. The center axis of the reflective layer 14d and the center axis of the reflective layer 14c may substantially coincide with each other.

The reflective layer 14d has an opening 14d1 at a bottom portion of the concave surface shape. The opening 14d1 can extract the light L reflected between the reflective layer 14c and the reflective layer 14d, in the front direction D_{Z}. A shape of the opening 14d1 in plan view is, for example, a substantially circular shape, a substantially elliptical shape, a substantially polygonal shape, or the like. The polygonal shape is, for example, a quadrangular shape, a hexagonal shape, or the like. The reflective layer 14c is provided between the opening 14d1 of the reflective layer 14d and the light emitting element 20.

A ratio Rₐ ((W₂/W₁)×100) of a size W₂ of the reflective layer 14c to a size W₁ of the first electrode 21 is preferably 30% or more and 80% or less. When the ratio Rₐ is 30% or more, light reflected by the reflective layer 14c can be maximized. Whereas, when the ratio Rₐ is 80% or less, light incident on the structure 14b from the light emitting element 20 can be maximized.

A ratio R_{b} ((W₃/W₁)×100) of a size W₃ of the opening 14d1 to the size W₁ of the first electrode 21 is preferably 30% or more and 80% or less. When the ratio R_{b} is 30% or more, light output from the opening 14d1 can be maximized. Whereas, when the ratio R_{b} is 80% or less, light reflected by the reflective layer 14d can be maximized.

A ratio R_{c} ((W₃/W₂)×100) of the size W₃ of the opening 14d1 to the size W₂ of the reflective layer 14c is preferably 30% or more and 80% or less. When the ratio R_{c} is 30% or more, light reflected by the reflective layer 14c and output from the opening 14d1 can be maximized. Whereas, when the ratio R_{b} is 80% or less, light reflected by the reflective layer 14d and the reflective layer 14c can be maximized.

The size W₁ of the first electrode 21 represents a size of the first electrode 21 in plan view. In a case where the size of the first electrode 21 varies depending on a direction, a maximum value of the sizes of the reflective layer 14c is set as the size W₁ of the first electrode 21. The size W₂ of the reflective layer 14c represents a size of the reflective layer 14c in plan view. In a case where the size of the reflective layer 14c varies depending on a direction, a maximum value of the sizes of the reflective layer 14c is set as the size W₂ of the reflective layer 14c. The size W₃ of the opening 14d1 represents a size of the opening 14d1 in plan view. In a case where the size of the opening 14d1 differs depending on a direction, a maximum value of the sizes of the opening 14d1 is set as the size W₃ of the opening 14d1.

As a material of the reflective layer 14d, a material similar to that of the reflective layer 14c can be exemplified.

### (Planarization Layer 15a)

The planarization layer 15a covers the plurality of reflective structures 14, and planarize unevenness formed by the plurality of reflective structures 14. The planarization layer 15a contains, for example, an inorganic material or a polymer resin. As the inorganic material, a material similar to the inorganic material of the protective layer 13 can be exemplified. As the polymer resin, a material similar to the polymer resin of the protective layer 13 can be exemplified.

A refractive index of the material contained in the planarization layer 15a is preferably lower than a refractive index of the material contained in the structure 14b. As a result, the light L output from the reflective structure 14 can be collected in the front direction D_{Z} by using refraction at an interface between the planarization layer 15a and the structure 14b.

### (Color Filter 16)

The color filter 16 is provided above the plurality of reflective structures 14. More specifically, the color filter 16 is provided on the first surface of the planarization layer 15a. The color filter 16 is an on-chip color filter (OCCF). The color filter 16 includes a plurality of red filter portions 16FR, a plurality of green filter portions 16FG, and a plurality of blue filter portions 16FB. Note that, in the following description, the red filter portions 16FR, the green filter portions 16FG, and the blue filter portions 16FB will be collectively referred to as filter portions 16F in a case where the red filter portions 16FR, the green filter portions 16FG, and the blue filter portions 16FB are not particularly distinguished from one another.

The plurality of filter portions 16F is two-dimensionally arranged on the first surface of the planarization layer 15a in a prescribed arrangement pattern similar to that of the plurality of light emitting elements 20. Each filter portion 16F is provided above the light emitting element 20. The light emitting element 20, and the reflective structure 14 and the red filter portion 16FR provided above the light emitting element 20 constitute the subpixel 100R. The light emitting element 20, and the reflective structure 14 and the green filter portion 16FG provided above the light emitting element 20 constitute the subpixel 100G. The light emitting element 20, and the reflective structure 14 and the blue filter portion 16FB provided above the light emitting element 20 constitute the subpixel 100B.

The red filter portion 16FR transmits red light in white light output from the reflective structure 14, and absorbs light other than the red light. The green filter portion 16FG transmits green light in white light output from the reflective structure 14, and absorbs light other than the green light. The blue filter portion 16FB transmits blue light in white light output from the reflective structure 14, and absorbs light other than the blue light.

The red filter portions 16FR include, for example, red color resist. The green filter portions 16FG include, for example, green color resist. The blue filter portions 16FB include, for example, blue color resist.

### (Planarization Layer 15b)

The planarization layer 15b is provided on the first surface of the color filter 16, and planarizes unevenness of the first surface of the color filter 16. The planarization layer 15b contains, for example, an inorganic material or a polymer resin. As the inorganic material, a material similar to the inorganic material of the protective layer 13 can be exemplified. As the polymer resin, a material similar to the polymer resin of the protective layer 13 can be exemplified.

### (Lens Array 17)

The lens array 17 includes a plurality of lenses 17a. The lens array 17 is provided above the plurality of reflective structures 14. The plurality of lenses 17a is two-dimensionally arranged on the first surface of the planarization layer 15b in a prescribed arrangement pattern similar to that of the plurality of light emitting elements 20. Each lens 17a is provided above the light emitting element 20. The lens 17a is an on-chip microlens. The lens 17a collects the light L output upward from the filter portion 16F, in the front direction D_{Z}. The lens 17a has, for example, a convex surface protruding in the front direction D_{Z}.

The convex surface is, for example, a convex curved surface or a frustum surface. The convex curved surface has, for example, a dome shape. Specifically, the convex curved surface having a dome shape is, for example, a substantially parabolic surface, a substantially hemispherical surface, a substantially semielliptical surface, or the like. The frustum surface is, for example, a substantially truncated cone surface, a substantially elliptical frustum surface, or a substantially truncated pyramid surface. The substantially truncated pyramid surface is, for example, a substantially quadrangular truncated pyramid surface or a substantially hexagonal truncated pyramid surface. A center axis of the lens 17a and the center axis of the reflective structure 14 preferably substantially coincide with each other.

The lenses 17a contain, for example, an inorganic material or a polymer resin transparent to visible light. The inorganic material contains, for example, silicon oxide (SiOx). The polymer resin includes, for example, an acrylic resin. The lens 17a may contain an ultraviolet curable resin.

### (Filling Resin Layer 18)

The filling resin layer 18 is provided between the lens array 17 and the counter substrate 19. The filling resin layer 18 has a function as an adhesive layer for bonding the lens array 17 and the counter substrate 19. The filling resin layer 18 includes, for example, at least one selected from a group including a thermosetting resin, an ultraviolet curable resin, and the like.

### (Counter Substrate 19)

The counter substrate 19 seals each member provided on the first surface of the circuit board 11. The counter substrate 19 has transparency to visible light, for example. The counter substrate 19 is provided on the first surface of the filling resin layer 18, and faces the circuit board 11. The counter substrate 19 is, for example, a glass substrate.

### [Method for Manufacturing Display Device 10]

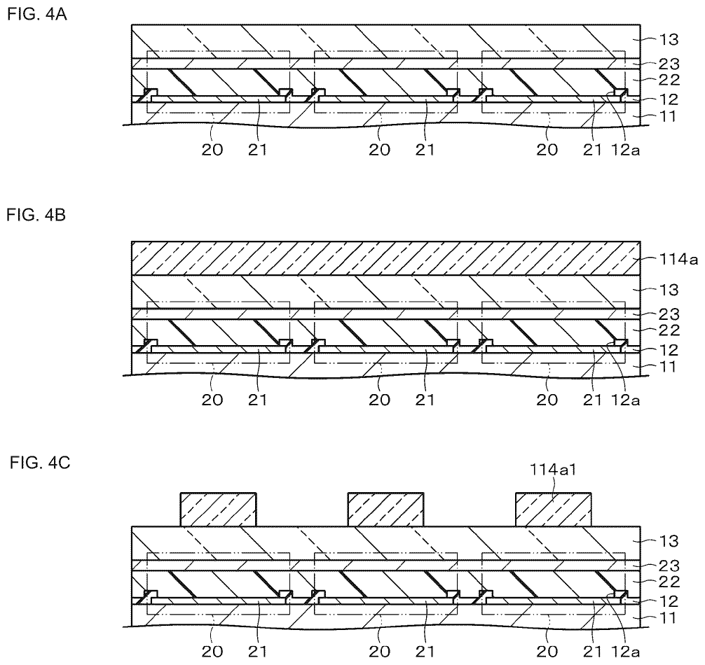

Hereinafter, with reference to FIGS. 4A to 4B, 5A to 5C, 6A to 6C, and 7A to 7C, an example of a method for manufacturing the display device 10 according to one embodiment will be described.

### (Step of Forming First Electrode 21)

First, a metal layer and a metal oxide layer are sequentially formed on the first surface of the circuit board 11 by, for example, a sputtering method, and then the metal layer and the metal oxide layer are patterned by using, for example, a photolithography technique and an etching technique. As a result, the plurality of first electrodes 21 is thus formed on the first surface of the circuit board 11.

### (Step of Forming Insulating Layer 12)

Next, the insulating layer 12 is formed on the first surface of the circuit board 11 so as to cover the plurality of first electrodes 21 by, for example, a chemical vapor deposition (CVD) method. Next, the opening 12a is formed in a portion of the insulating layer 12 located on the first surface of each of the first electrodes 21 by, for example, a photolithography technique and a dry etching technique.

### (Step of Forming OLED Layer 22)

Next, a hole transport layer, a red light emitting layer, a light emitting separation layer, a blue light emitting layer, a green light emitting layer, an electron transport layer, and an electron injection layer are stacked in that order on the first surfaces of the plurality of first electrodes 21 and on the first surface of the insulating layer 12 by, for example, a vapor deposition method, to form the OLED layer 22.

### (Step of Forming Second Electrode 23)

Next, the second electrode 23 is formed on the first surface of the OLED layer 22 by, for example, the vapor deposition method or the sputtering method. As a result, the plurality of light emitting elements 20 is thus formed on the first surface of the circuit board 11.

### (Step of Forming Protective Layer 13)

Next, as illustrated in FIG. 4A, the protective layer 13 is formed on the first surface of the second electrode 23 by, for example, a CVD method or a vapor deposition method.

### (Step of Forming Structure 14a)

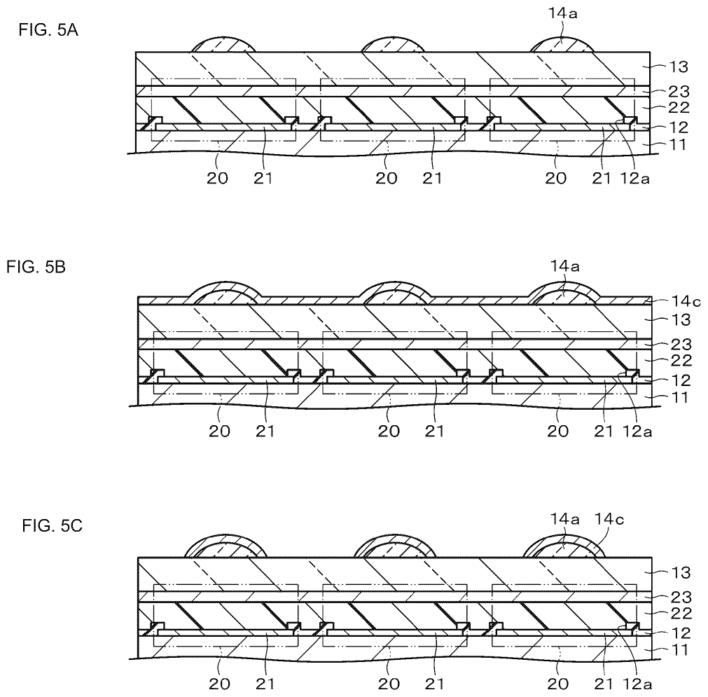

Next, as illustrated in FIG. 4B, a lens material is applied to the first surface of the protective layer 13 by, for example, a spin coating method, and cured to form a lens material layer 114a. Next, the lens material layer 114a is patterned by, for example, a photolithography technique and a dry etching technique. As a result, as illustrated in FIG. 4C, a plurality of lens material layers 114a1 having an island shape (for example, a substantially cylindrical shape) is formed at formation positions of the individual light emitting element 20 (that is, formation positions of individual subpixels 100). Next, each island-shaped lens material layer 114a1 is melted and then cured by reflow, for example. As a result, as illustrated in FIG. 5A, the plurality of structures 14a having a convex surface is formed on the first surface of the protective layer 13.

### (Step of Forming Reflective Layer 14c)

Next, as illustrated in FIG. 5B, the reflective layer 14c is formed on the first surface of the protective layer 13 by, for example, a sputtering method so as to follow the plurality of structures 14a. Next, the reflective layer 14c is removed from the flat portion between adjacent structures 14a by, for example, a photolithography technique and a dry etching technique. As a result, as illustrated in FIG. 5C, the reflective layer 14c remains only on the convex surface of each structure 14a.

### (Step of Forming Structure 14b)

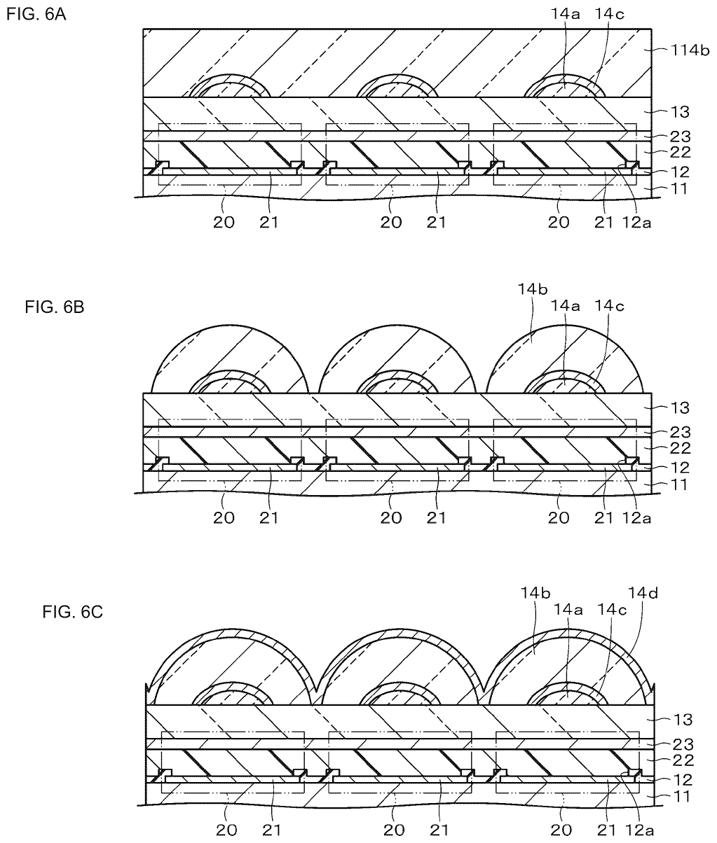

Next, as illustrated in FIG. 6A, a lens material is applied to the first surface of the protective layer 13 by, for example, a spin coating method, and cured to form a lens material layer 114b. At this time, an application condition of the lens material is adjusted such that the first surface of the lens material layer 114b is at a position sufficiently higher than the reflective layer 14c. Next, similarly to the step of forming the structure 14a, after the lens material layer 114a is patterned, the lens material layer 114a is melted and cured. As a result, as illustrated in FIG. 6B, the structure 14b having the convex surface is formed on each reflective layer 14c.

### (Step of Forming Reflective Layer 14d)

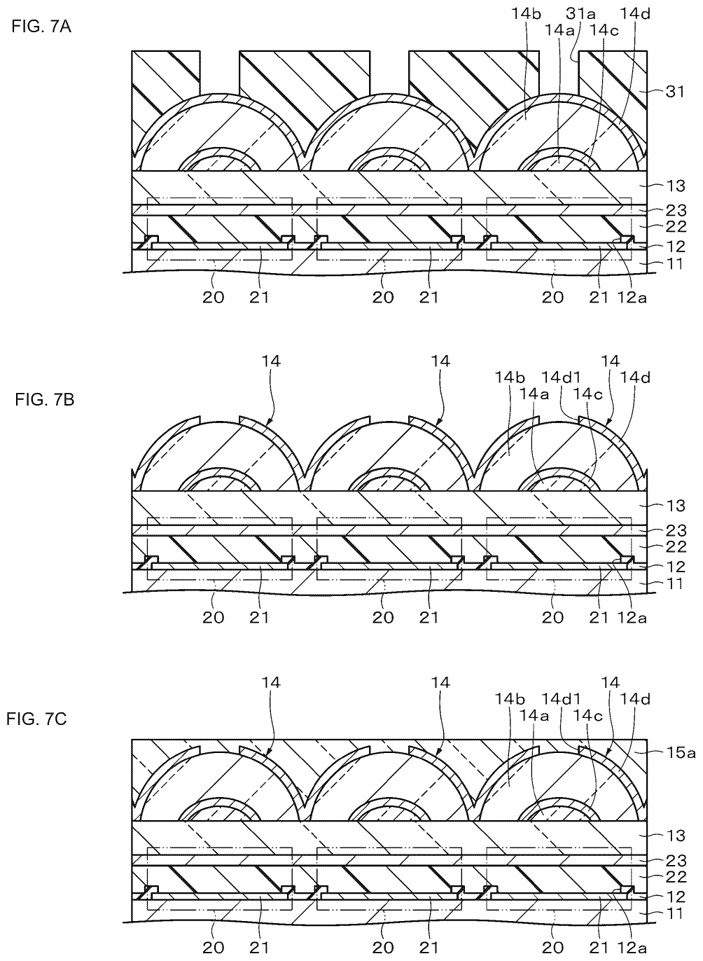

Next, as illustrated in FIG. 6C, the reflective layer 14d is formed on the first surface of the protective layer 13 by, for example, a sputtering method so as to follow the plurality of the structures 14b. Next, a resist is applied and cured on the first surface of the reflective layer 14d by, for example, a spin coating method, and then the resist is exposed and developed. As a result, as illustrated in FIG. 7A, a resist layer 31 having a plurality of openings 31a is formed on the first surface of the reflective layer 14d. At this time, each opening 31a is formed on a top portion of the reflective layer 14d.

Next, the reflective layer 14d is dry-etched via the resist layer 31 to form the opening 14d1 at each top portion of the reflective layer 14d, and then the resist layer 31 is removed. As a result, as illustrated in FIG. 7B, the plurality of reflective structures 14 is formed on the first surface of the protective layer 13.

### (Step of Forming Planarization Layer 15a)

Next, as illustrated in FIG. 7C, the planarization layer 15a is formed on the plurality of reflective structures 14 by, for example, a CVD method or a vapor deposition method.

### (Step of Forming Color Filter 16)

Next, a coloring composition for forming a green filter portion is applied onto the first surface of the planarization layer 15a, and after pattern exposure by irradiation with ultraviolet rays through a photomask, development is performed to form the green filter portion 16FG. Next, a coloring composition for forming a red filter portion is applied onto the first surface of the planarization layer 15a, and after pattern exposure by irradiation with ultraviolet rays through a photomask, development is performed to form the red filter portion 16FR. Next, a coloring composition for forming a blue filter portion is applied onto the first surface of the planarization layer 15a, and after pattern exposure by irradiation with ultraviolet rays through a photomask, development is performed to form the blue filter portion 16FB. As a result, the color filter 16 is formed on the first surface of the planarization layer 15a.

### (Step of Forming Planarization Layer 15b)

Next, the planarization layer 15b is formed on the first surface of the color filter 16 by, for example, a CVD method or a vapor deposition method.

### (Step of Forming Lens Array 17)

Next, a lens material is applied to the first surface of the protective layer 13 by, for example, a spin coating method, and cured to form a lens material layer. Next, the lens material layer is patterned in an island shape (for example, a substantially cylindrical shape) by, for example, a photolithography technique and a dry etching technique, and then each lens material layer in the island shape is melted and cured by reflow. As a result, the plurality of lenses 17a having the convex surface is formed on the first surface of the planarization layer 15b.

### (Step of Sealing)

Next, the circuit board 11 and the counter substrate 19 in which the individual members are formed on the first surface as described above are bonded to each other by the filling resin layer 18. As a method for forming the filling resin layer 18, for example, a one drop fill (ODF) method can be used. From above, the display device 10 illustrated in FIG. 3 is obtained.

### [Action and Effect]

The display device 10 according to one embodiment includes the reflective structure 14 above the light emitting element 20, and the reflective structure 14 has a concave shape concaved in a direction away from the light emitting element 20, and includes the reflective layer 14d having the opening 14d1 in a central portion of the concave shape and the reflective layer (reflector) 14c provided between the opening 14d1 and the light emitting element 20. As a result, as illustrated in FIG. 3, the light L output from the light emitting element 20 to the wide-angle side is repeatedly reflected between the reflective layer 14c and the reflective layer 14d, so that the light L can be extracted from the opening 14d1. Therefore, the light L output from the light emitting element 20 to the wide-angle side can be collected on the own subpixel 100. Therefore, color purity and luminous efficiency can be improved.

The display device described in Patent Document 1 is a structure in which light emitted by the organic electroluminescence layer is guided between the first electrode and the second electrode and extracted from a light transmission part of the second electrode, so that an area of a light emitting region is reduced.

Whereas, in the display device 10 according to one embodiment, the reflective structure 14 capable of collecting the light L output from the light emitting element 20 to the wide-angle side is provided separately from the first electrode 21 and the second electrode 23. Therefore, a decrease in the area of the light emitting region can be suppressed.

In the display device described in Patent Document 1, the first electrode, the organic electroluminescence layer, and the second electrode are laminated on a convex base, so that a thickness of the organic electroluminescence layer becomes uneven, and characteristic defects such as color shift of emission color occur.

Whereas, in the display device 10 according to one embodiment, the first electrode 21 has a planar shape, so that the OLED layer 22 can be made substantially uniform, and characteristic defects such as color shift of the emission color can be suppressed.

In the display device 10 according to one embodiment, a light collection characteristic can be adjusted to a desired one by adjusting a positional relationship among the reflective layer 14c, the reflective layer 14d, and the lens 17a.

### 2 Modification

### <Modification 1>

[Configuration of Display Device 10a]

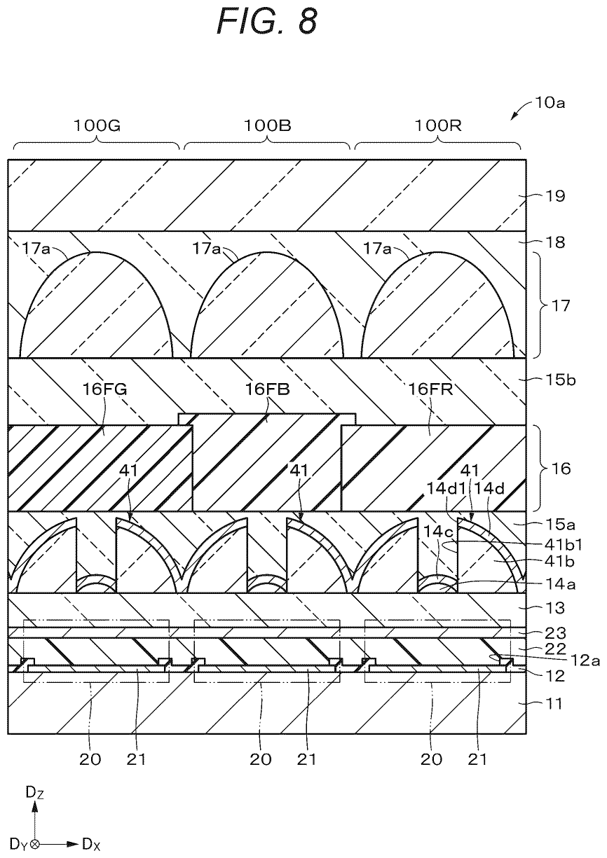

FIG. 8 is a cross-sectional view illustrating an example of a configuration of a display device 10a according to Modification 1. The display device 10a is different from the display device 10 according to one embodiment in including a plurality of reflective structures 41 instead of the plurality of reflective structures 14 (see FIG. 3).

### (Reflective Structure 41)

The reflective structure 41 includes a structure 41b having a hole portion 41b1. A part of the planarization layer 15a enters the hole portion 41b1. The hole portion 41b1 is provided from the opening 14d1 of the reflective layer 14d up to a position of the first surface of the reflective layer 14c in a thickness direction of the display device 10a. The reflective structure 41 is similar to the reflective structure 14 of one embodiment in points other than the above.

[Method for Manufacturing Display Device 10a]

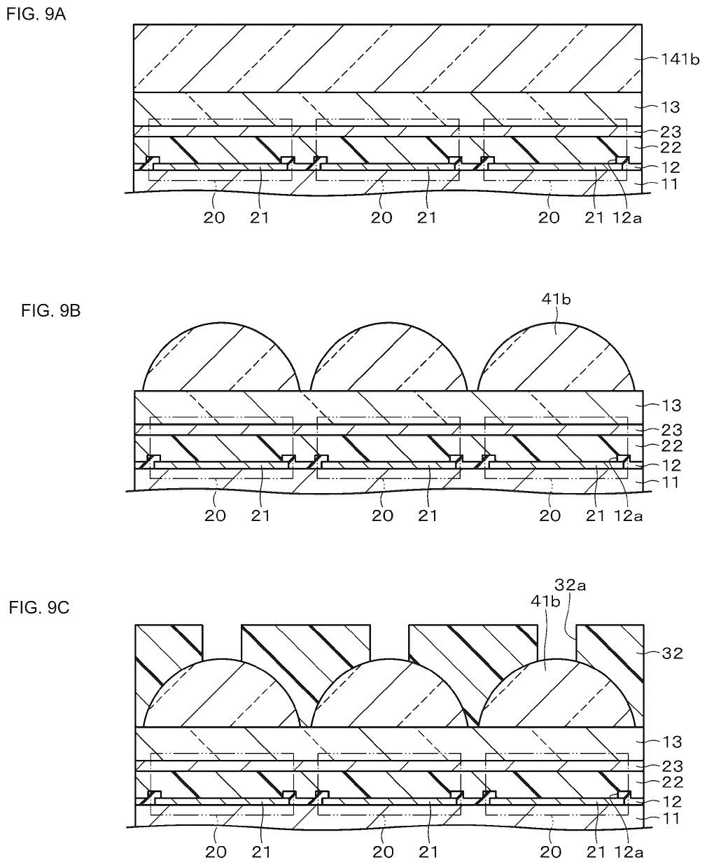

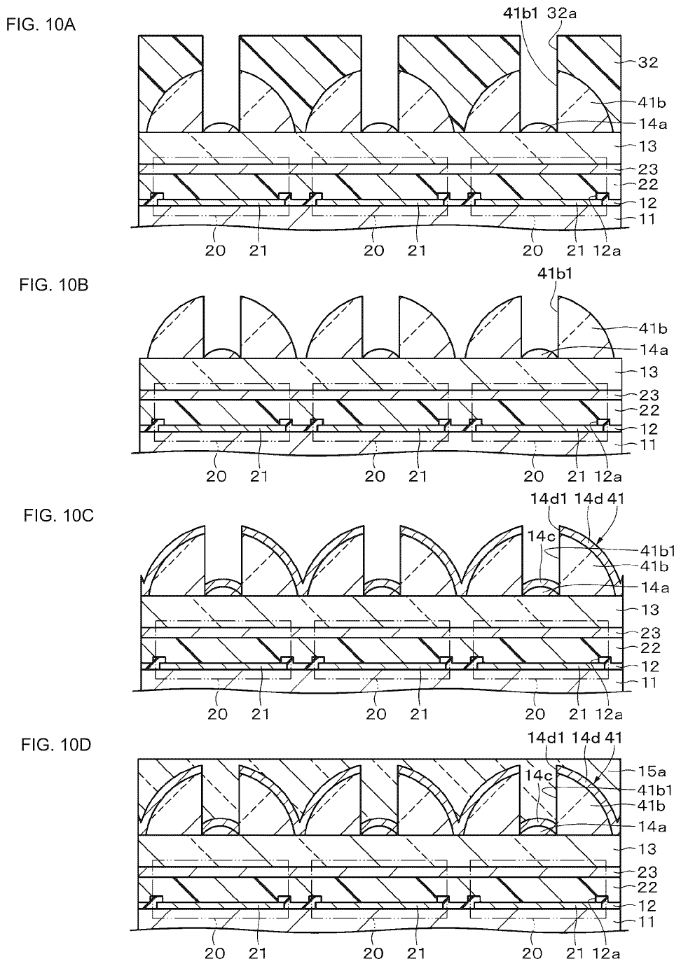

Hereinafter, with reference to FIGS. 9A to 9C and 10A to 10D, an example of a method for manufacturing the display device 10a according to Modification 1 will be described.

(Steps from Step of Forming First Electrode 21 to Step of Forming Protective Layer 13)

First, steps from a step of forming the first electrode 21 to a step of forming the protective layer 13 are performed similarly to the method for manufacturing the display device 10 according to the first embodiment.

### (Step of Forming Structure 14a and Structure 41b)

Next, as illustrated in FIG. 9A, a lens material is applied to the first surface of the protective layer 13 by, for example, a spin coating method, and cured to form a lens material layer 141b. Next, the lens material layer 141b is patterned by, for example, a photolithography technique and a dry etching technique. As a result, a plurality of lens material layers having an island shape (for example, a substantially cylindrical shape) is formed at formation positions of the individual light emitting elements 20 (that is, formation positions of individual subpixels 100). Next, each island-shaped lens material layer is melted and then cured by reflow, for example. As a result, as illustrated in FIG. 9B, the plurality of the structures 41b having the convex surface is formed on the first surface of the protective layer 13.

Next, a resist is applied and cured on the convex surfaces of the plurality of structures 41b and the first surface of the protective layer 13 by, for example, a spin coating method, and then the resist is exposed and developed. As a result, as illustrated in FIG. 9C, a resist layer 32 having the plurality of openings 32a is formed on the convex surface of the structure 41b and the first surface of the protective layer 13. At this time, each opening 32a is formed on a top portion of the convex surface of the structure 41b.

Next, by dry-etching the structure 41b via the resist layer 32, as illustrated in FIG. 10A, the hole portion 41b1 is formed in the structure 41b, and the structure 14a is formed at a bottom portion of the hole 41b1. The structure 14a is formed by adjusting etching conditions. Next, as illustrated in FIG. 10B, the resist layer 32 is removed from the convex surfaces of the plurality of structures 41b and the first surface of the protective layer 13 by ashing, for example.

### (Step of Forming Reflective Layer 14c and Reflective Layer 14d)

Next, as illustrated in FIG. 10C, the reflective layer 14c is formed on the convex surface of the structure 14a, and the reflective layer 14d is formed on the convex surface of the structure 41b, for example, by a film forming method with high covering property such as atomic layer deposition (ALD). Next, constituent materials of the reflective layers 14c and 14d attached to side walls of the hole portion 41b1 are removed by, for example, an etch back method. As a result, the plurality of reflective structures 41 is formed on the first surface of the protective layer 13.

### (Step of Forming Planarization Layer 15a)

Next, as illustrated in FIG. 10D, the planarization layer 15a is formed on the plurality of reflective structures 41 by, for example, a CVD method or a vapor deposition method. At this time, the hole portion 41b1 of the structure 41b is filled with the planarization layer 15a.

(Steps from Step of Forming to Step of Sealing of Color Filter 16)

Next, steps from a step of forming to a step of sealing of the color filter 16 are performed similarly to the first embodiment. From above, the display device 10a illustrated in FIG. 8 is obtained.

In the method for manufacturing the display device 10a according to Modification 1, the reflective layer 14c and the reflective layer 14d can be formed by self-alignment using the hole portion 41b1. Therefore, positional misalignment of the center axes of the reflective layer 14c and the reflective layer 14d can be suppressed.

### <Modification 2>

[Configuration of Display Device 10b]

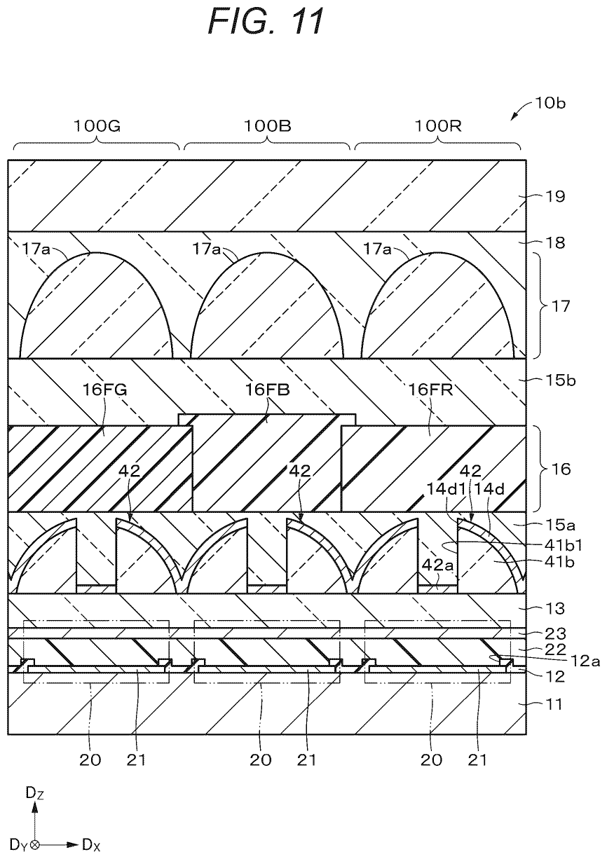

FIG. 11 is a cross-sectional view illustrating an example of a configuration of a display device 10b according to Modification 2. The display device 10b is different from the display device 10 according to one embodiment in including a plurality of reflective structures 42 instead of the plurality of reflective structures 14 (see FIG. 3).

### (Reflective Structure 42)

The reflective structure 42 includes a reflective layer 42a, the structure 41b, and the reflective layer 14d. The reflective layer 42a has a planar shape perpendicular to a thickness direction of the light emitting element 20. As a material of the reflective layer 42a, a material similar to that of the reflective layer 14c can be exemplified. The reflective layer 42a may be provided on the first surface of the protective layer 13, or may be provided above the first surface of the protective layer 13 while being separated from the first surface of the protective layer 13. The reflective structure 42 is similar to the reflective structure 41 of Modification 1 in points other than the above.

[Method for Manufacturing Display Device 10b]

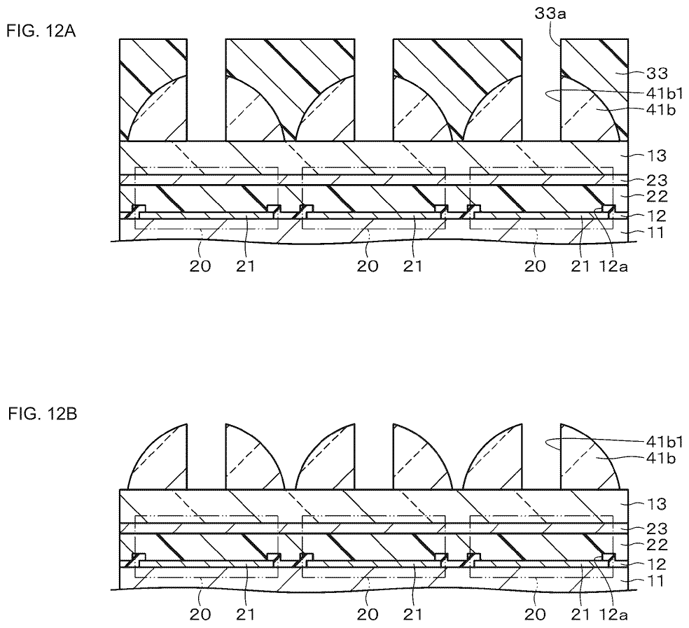

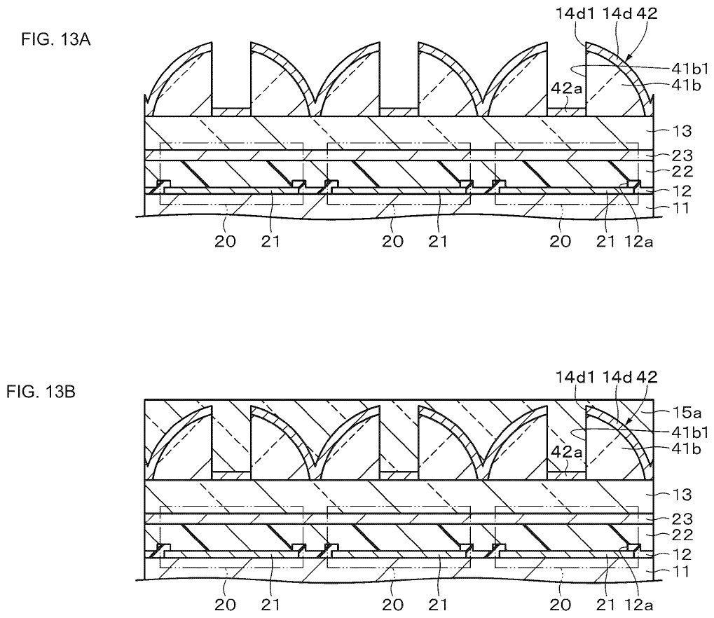

Hereinafter, with reference to FIGS. 12A, 12B, 13A, and 13B, an example of a method for manufacturing the display device 10b according to Modification 2 will be described.

(Steps from Step of Forming First Electrode 21 to Step of Forming Protective Layer 13)

First, steps from a step of forming the first electrode 21 to a step of forming the protective layer 13 are performed similarly to the method for manufacturing the display device 10 according to the first embodiment.

### (Step of Forming Structure 41b)

Next, by adjusting etching conditions, as illustrated in FIG. 12A, the plurality of structures 41b is formed on the first surface of the protective layer 13 similarly to the step of forming of the structures 14a and 41b of Modification 1 except that a bottom portion of the hole portion 41b1 is made flat and the structure 14a is not formed. Next, as illustrated in FIG. 12B, a resist layer 33 is removed from the convex surfaces of the plurality of structures 41b and the first surface of the protective layer 13 by ashing, for example.

### (Step of Forming Reflective Layer 14c and Reflective Layer 14d)

Next, as illustrated in FIG. 13A, the reflective layer 14c is formed on a convex surface of the structure 14a, and the reflective layer 14d is formed on the flat surface of the bottom portion of the hole portion 41b1 by, for example, a sputtering method. As a result, the plurality of reflective structures 42 is formed on the first surface of the protective layer 13.

### (Step of Forming Planarization Layer 15a)

Next, as illustrated in FIG. 13B, the planarization layer 15a is formed on the plurality of reflective structures 42 by, for example, a CVD method or a vapor deposition method. At this time, the hole portion 41b1 of the structure 41b is filled with the planarization layer 15a.

(Steps from Step of Forming to Step of Sealing of Color Planarization Layer 15a)

Next, steps from a step of forming to a step of sealing of the color the planarization layer 15a are performed similarly to the first embodiment. From above, the display device 10a illustrated in FIG. 11 is obtained.

### <Modification 3>

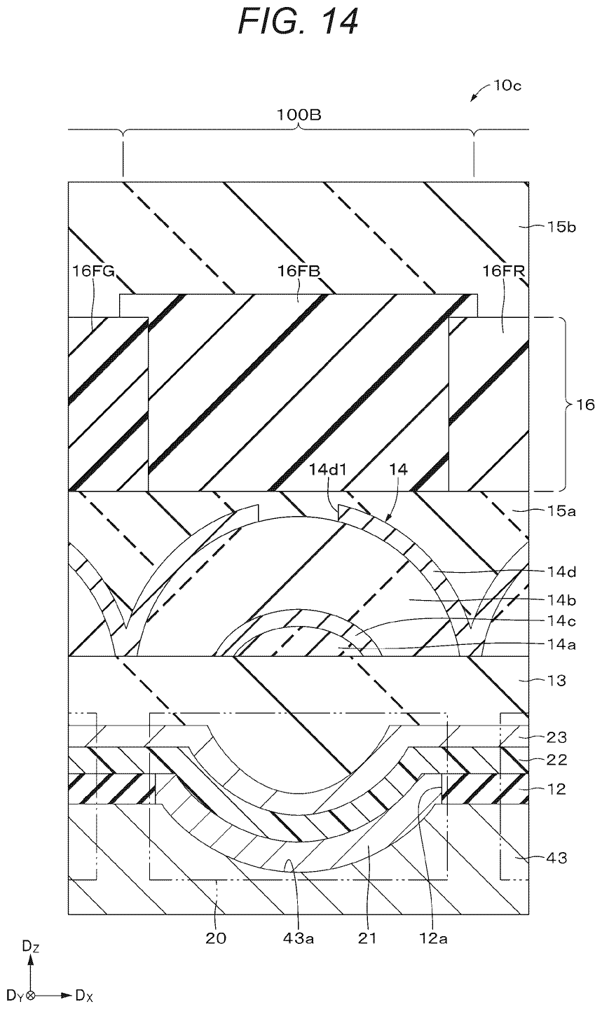

FIG. 14 is a cross-sectional view illustrating an example of a configuration of a display device 10c according to Modification 3. The display device 10c includes the circuit board 43 having a plurality of concave portions 43a on the first surface, instead of the circuit board 11 (see FIG. 3).

The concave portion 43a has a concave curved surface concaved in a direction away from the reflective structure 14. The curved surface is, for example, a substantially parabolic surface, a substantially hemispherical surface, a substantially semielliptical surface, or the like. The plurality of concave portions 43a is provided at arrangement positions of the individual light emitting elements 20. The light emitting element 20 follows the curved surface of the concave portion 43a. More specifically, the first electrode 21, the OLED layer 22, and the second electrode 23 follow the curved surface of the concave portion 43a. A thickness of the OLED layer 22 is preferably substantially uniform from the viewpoint of suppressing characteristic defects such as color shift of the emission color.

Since the light emitting element 20 follows the curved surface of the concave portion 43a as described above, the first electrode 21 included in the light emitting element 20 is curved in a concave shape. As a result, since light emitted from the OLED layer 22 is reflected by the first electrode 21, which is curved in the concave shape, toward the front direction, the light extraction efficiency can be further improved.

### <Modification 4>

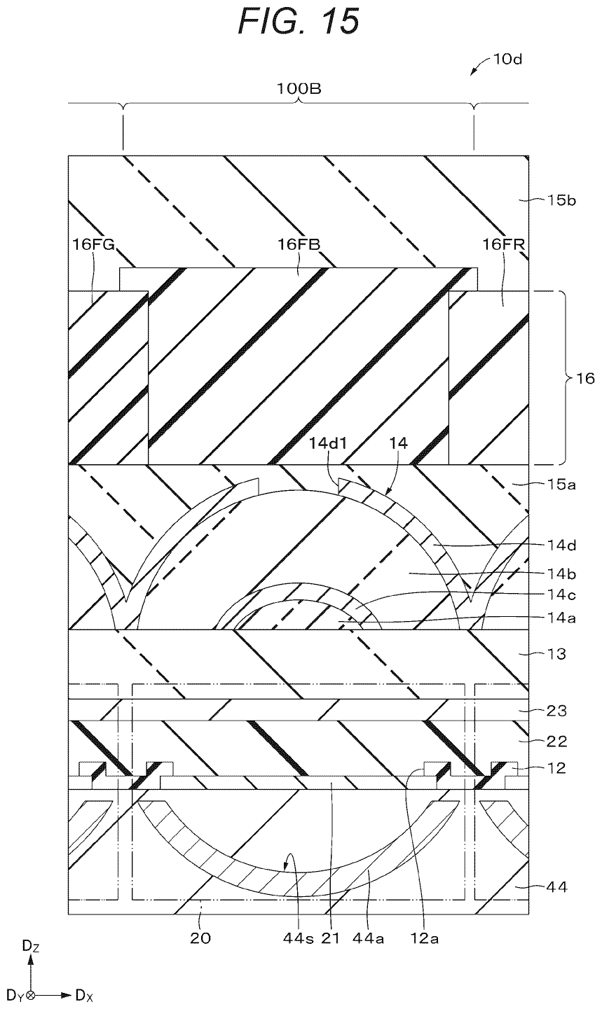

FIG. 15 is a cross-sectional view illustrating an example of a configuration of a display device 10d according to Modification 4. The display device 10d includes a circuit board 44 including a plurality of reflective layers 44a therein instead of the circuit board 11 (see FIG. 3).

The reflective layer 44a is an example of a second reflective layer. The reflective layer 44a has a curved shape concaved in a direction away from the light emitting element 20. A curved surface 44s of the reflective layer 44a is, for example, a substantially parabolic surface, a substantially hemispherical surface, a substantially semi-elliptical surface, or the like. The plurality of reflective layers 44a is provided below the individual light emitting element 20. That is, the OLED layer 22 is provided above the reflective layer 44a. As a material of the reflective layer 44a, a material similar to that of the reflective layer 14c can be exemplified.

In the display device 10d according to Modification 4, the first electrode 21 is a transparent electrode having transparency to visible light. The transparent electrode includes, for example, at least one of a metal layer or a transparent conductive oxide layer. As materials of the metal layer and the transparent conductive oxide layer, materials similar to those of the metal layer and the transparent conductive oxide layer in the second electrode can be exemplified.

As described above, when the display device 10d includes the reflective layer 44a below each light emitting element 20, light emitted from the OLED layer 22 is reflected toward the front direction by the reflective layer 44a curved in the concave shape, so that the light extraction efficiency can be further improved.

In the example described above, an example has been described in which the reflective layer 44a is divided between adjacent subpixels 100 and separately provided for the plurality of subpixels 100, but the reflective layer 44a may be connected between the adjacent subpixels 100.

### <Modification 5>

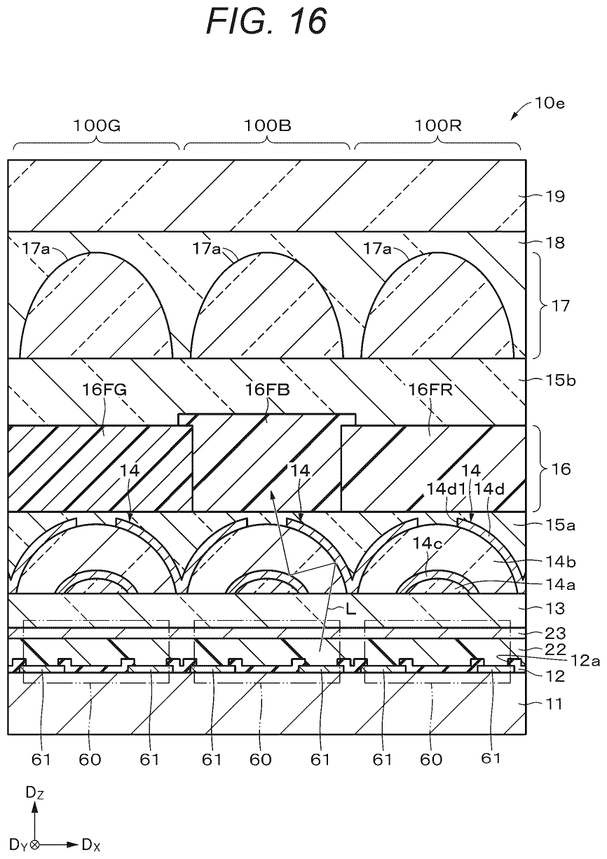

FIG. 16 is a cross-sectional view illustrating an example of a configuration of a display device 10e according to Modification 5. The display device 10e includes a plurality of light emitting elements 60 instead of the plurality of light emitting elements 20 (see FIG. 3).

The light emitting element 60 is similar to the reflective structure 14 of one embodiment except that a first electrode 61 is provided instead of the first electrode 21. The first electrode 61 has a ring shape in plan view. The ring shape is, for example, a circular ring shape, an elliptical ring shape, or a polygonal ring shape. The polygonal ring shape is, for example, a quadrangular ring shape or a hexagonal ring shape. The first electrode 61 is preferably provided below a ring region between a peripheral edge of the reflective layer 14c and a peripheral edge of the reflective layer 14d. As a result, the light L output upward from the OLED layer 22 and the light L output downward from the OLED layer 22 and reflected upward by the first electrode 61 can be allowed to enter between the reflective layer 14c and the reflective layer 14d from the ring region described above. Therefore, an amount of light extracted from the reflective structure 14 can be increased. From the viewpoint of increasing the amount of light extracted from the reflective structure 14, the first electrode 61 preferably has a shape similar to that of the ring region between the peripheral edge of the reflective layer 14c and the peripheral edge of the reflective layer 14d.

### <Modification 6>

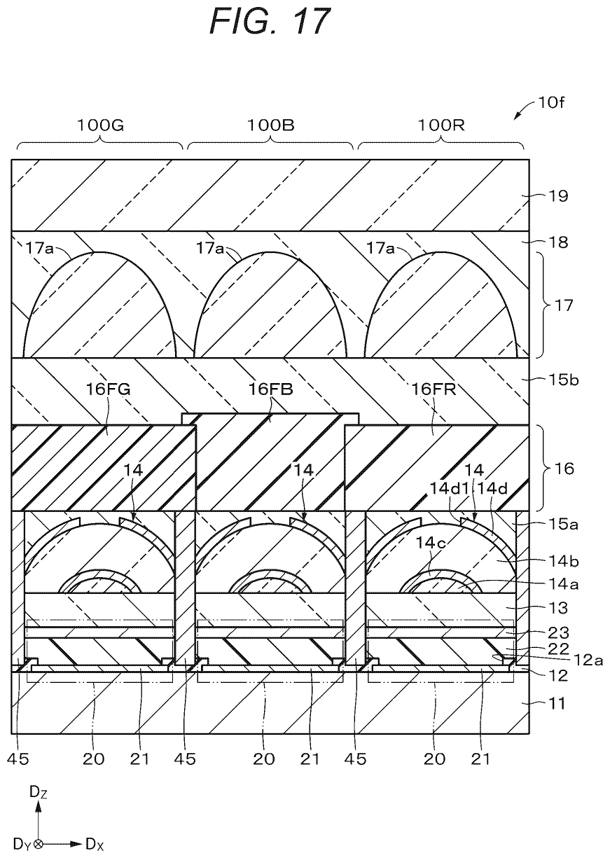

FIG. 17 is a cross-sectional view illustrating an example of a configuration of a display device 10f according to Modification 6. The display device 10f includes a partition wall 45 between adjacent subpixels 100. The partition wall 45 is a reflection wall that reflects light output from the light emitting element 20 to the wide-angle side.

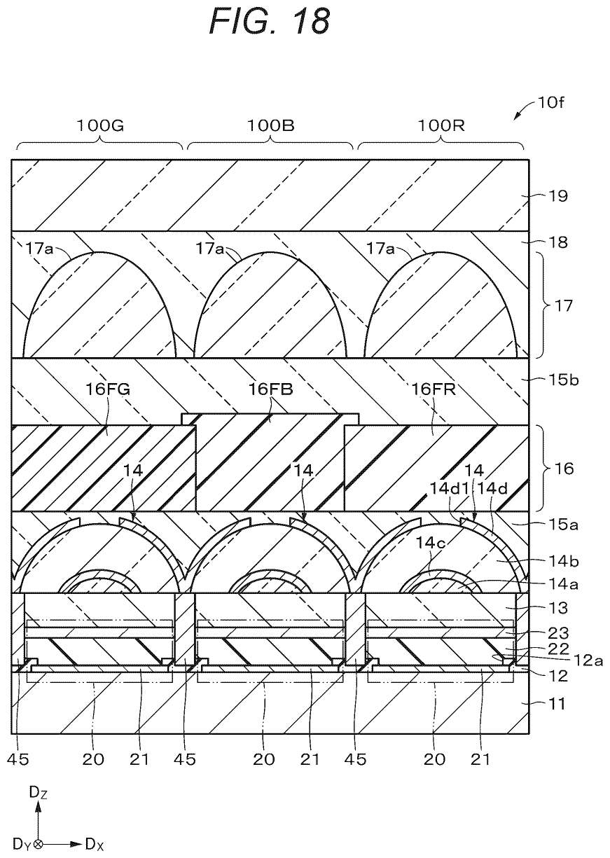

The partition wall 45 is provided on the first surface of the insulating layer 12, and is raised perpendicularly with respect to the first surface of the circuit board 11. An upper end of the partition wall 45 may be in contact with the second surface of the color filter 16 or may be located in the planarization layer 15a. However, a position of the upper end of the partition wall 45 is not limited to these examples. For example, as illustrated in FIG. 18, the upper end of the partition wall 45 may be located at the same height as bottom portions of the plurality of reflective structures 14, may be located in the protective layer 13, or may be located at the same height as the second electrode 23.

The partition wall 45 may have a ring shape surrounding a periphery of the light emitting element 20 in plan view. The partition wall 45 may be provided in a part of the periphery of the light emitting element 20. In this case, the partition wall 45 may be provided in a portion in the horizontal direction, a portion in the vertical direction, or both of the portions in the periphery of the light emitting element 20.

The partition wall 45 contains metal or polymer resin. As the metal, a material similar to that of the reflective layer 14c can be exemplified, and at least one selected from the group consisting of aluminum (Al) and silver (Ag) is particularly preferable among these metals, from the viewpoint of improving the reflectance. In a case where the partition wall 45 contains metal, an insulating material may be provided on a wall surface of the partition wall 45, or an insulating material may be provided on the wall surface and the upper end of the partition wall 45.

A refractive index of the polymer resin is preferably lower than a refractive index of the OLED layer 22. As a result, light output from the light emitting element 20 to the wide-angle side can be totally reflected by the partition wall 45. In the present specification, the refractive index represents a refractive index for visible light. The polymer resin includes, for example, at least one selected from a group including a thermosetting resin, an ultraviolet curable resin, and the like. Specifically, the polymer resin includes, for example, at least one selected from the group from an acrylic resin, a polyimide resin, a novolac resin, an epoxy resin, a norbornene resin, and the like.

In the display device 10f according to Modification 3, light output from the light emitting element 20 to the wide-angle side can be reflected by the partition wall 45 and allowed to enter the reflective structure 14. Therefore, light collecting property of light to the own subpixel 100 can be further enhanced.

### <Modification 7>

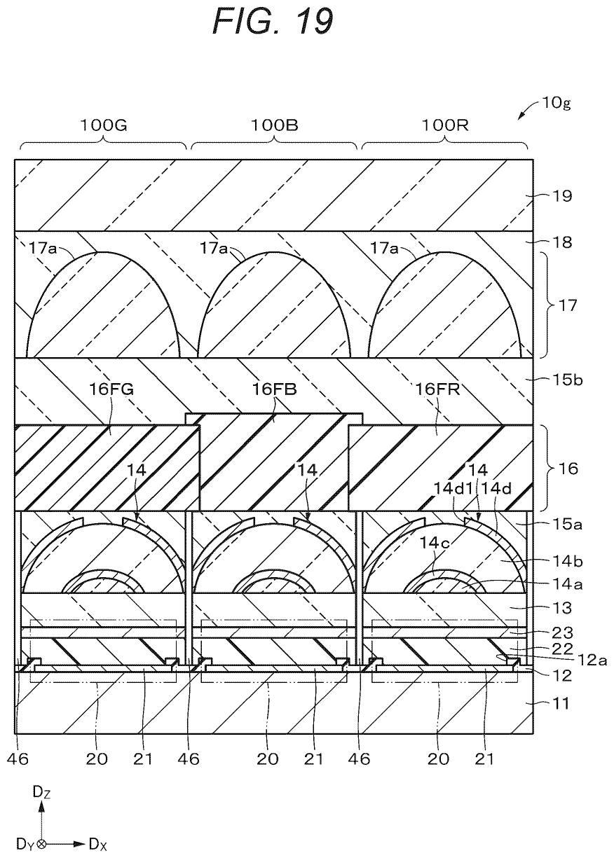

FIG. 19 is a cross-sectional view illustrating an example of a configuration of a display device 10g according to Modification 7. The display device 10g has a gap 46 instead of the partition wall 45 (see FIG. 17) between adjacent subpixels 100. A formation position, a shape, and a height of the gap 46 can be made similar to the formation position, the shape, and the height of the partition wall 45. The gap 46 includes, for example, a gas such as air.

In the display device 10g according to Modification 7, similarly to the display device 10f of Modification 6, light output from the light emitting element 20 to the wide-angle side can be reflected by the gap 46 and allowed to enter the reflective structure 14. Therefore, light collecting property of light to the own subpixel 100 can be further enhanced.

### <Modification 8>

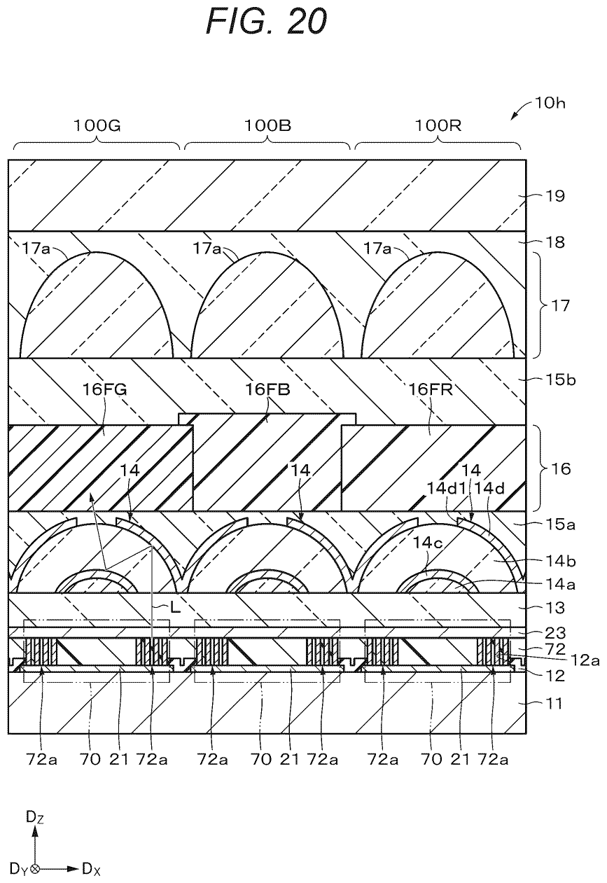

FIG. 20 is a cross-sectional view illustrating an example of a configuration of a display device 10h according to Modification 8. The display device 10h includes a plurality of light emitting elements 70 instead of the plurality of light emitting elements 20. The light emitting element 70 can emit white light, and allow the white light to enter as parallel light between the reflective layer 14c and the reflective layer 14d.

The light emitting element 70 includes the first electrode 21, an OLED layer 72, and the second electrode 23 sequentially on the first surface of the circuit board 11. The OLED layer 72 has a collimator structure 72a capable of converting emitted white light into parallel light parallel to the front direction D_{Z}, and allowing the parallel light to enter between the reflective layer 14c and the reflective layer 14d. The collimator structure 72a is preferably provided below a ring region between a peripheral edge of the reflective layer 14c and a peripheral edge of the reflective layer 14d. The collimator structure 72a is a microtube, a fine periodic structure, or the like.

In the display device 10h according to Modification 4, the OLED layer 72 can make the output light parallel to the front direction D_{Z} by using the collimator structure 72a, and allow the output light to enter between the reflective layer 14c and the reflective layer 14d. Therefore, light collecting property of light to the own subpixel 100 can be further enhanced.

### <Modification 9>

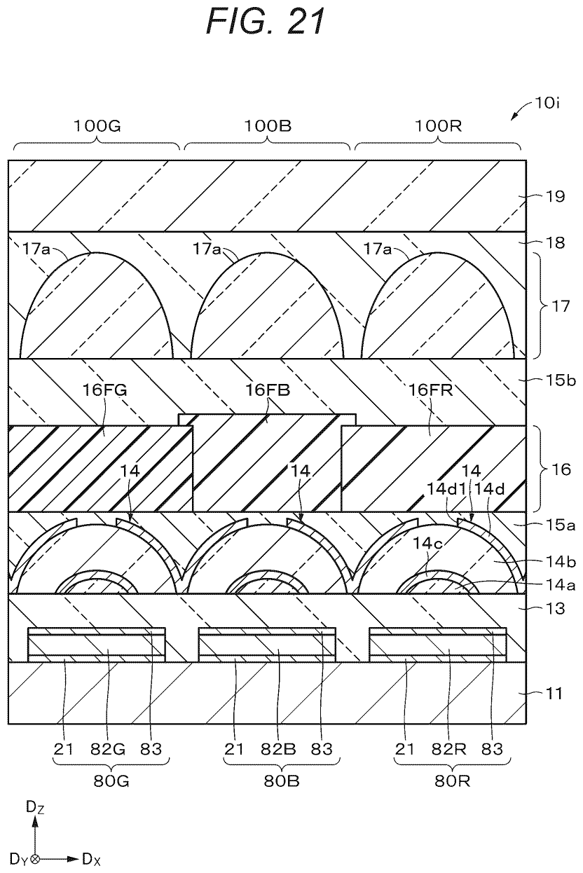

FIG. 21 is a cross-sectional view illustrating an example of a configuration of a display device 10i according to Modification 9. The display device 10i includes a plurality of light emitting elements 80R capable of emitting red light, a plurality of light emitting elements 80G capable of emitting green light, and a plurality of light emitting elements 80B capable of emitting blue light, instead of the plurality of light emitting elements 20 (see FIG. 3) capable of emitting white light. Although FIG. 21 illustrates an example in which the color filter 16 is provided, the color filter 16 may not be provided.

The light emitting element 80R is a red OLED element. The light emitting element 80R includes the first electrode 21, an OLED layer 82R, and a second electrode 93 sequentially on the first surface of the circuit board 11. The OLED layer 82R can emit red light by recombination of holes injected from the first electrode 21 and electrons injected from the second electrode 83.

The light emitting element 80G is a green OLED element. The light emitting element 80G includes the first electrode 21, an OLED layer 82G, and the second electrode 83 sequentially on the first surface of the circuit board 11. The OLED layer 82G can emit green light by recombination of holes injected from the first electrode 21 and electrons injected from the second electrode 83.

The light emitting element 80B is a blue OLED element. The light emitting element 80B includes the first electrode 21, an OLED layer 82B, and the second electrode 83 sequentially on the first surface of the circuit board 11. The OLED layer 82B can emit blue light by recombination of holes injected from the first electrode 21 and electrons injected from the second electrode 83.

The second electrode 83 is similar to the second electrode 23 of one embodiment except that the second electrode 83 is divided between adjacent light emitting elements 20 and separately provided for the plurality of light emitting elements 20.

### <Modification 10>

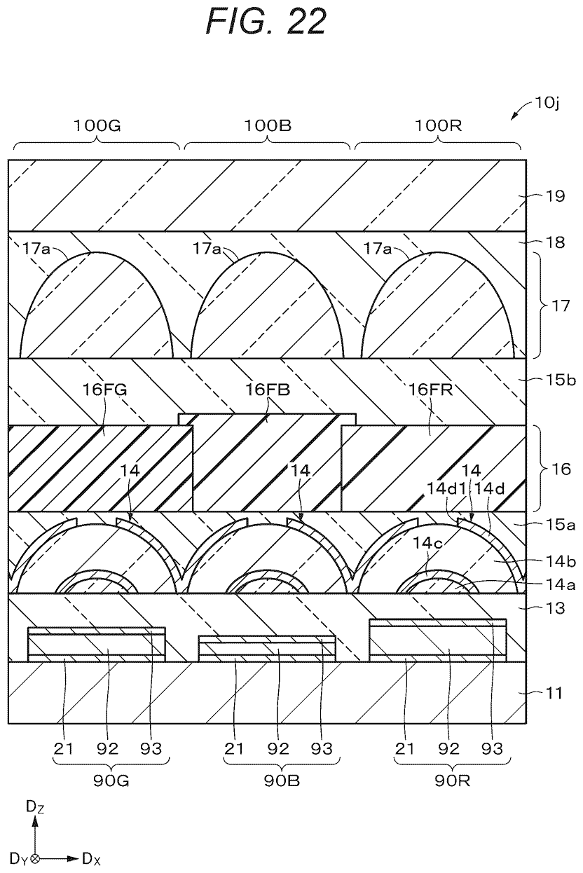

FIG. 22 is a cross-sectional view illustrating an example of a configuration of a display device 10j according to Modification 10. The display device 10j includes a plurality of light emitting elements 90R capable of outputting red light, a plurality of light emitting elements 90G capable of outputting green light, and a plurality of light emitting elements 90B capable of outputting blue light, instead of the plurality of light emitting elements 20 (see FIG. 3) capable of outputting white light. Although FIG. 22 illustrates an example in which the color filter 16 is provided, the color filter 16 may not be provided.

The light emitting element 90R is a red OLED element. The light emitting element 90R includes the first electrode 21, an OLED layer 92, and a second electrode 93 sequentially on the first surface of the circuit board 11. The OLED layer 92 can emit white light by recombination of holes injected from the first electrode 21 and electrons injected from the second electrode 93. The second electrode 93 is similar to the second electrode 23 of one embodiment except that the second electrode 93 is divided between adjacent light emitting elements 20 and separately provided for the plurality of light emitting elements 20.

The light emitting element 90R has a first resonator structure. The first resonator structure can resonate and emphasize red light included in white light emitted by the OLED layer 92. The first resonator structure includes the first electrode 21 and the second electrode 93. An optical path length between the first electrode 21 and the second electrode 93 in the light emitting element 90R may be set to a spectrum peak wavelength of the red subpixel 100R.

The light emitting element 90G is a green OLED element. The light emitting element 90G includes the first electrode 21, the OLED layer 92, and the second electrode 93 sequentially on the first surface of the circuit board 11.

The light emitting element 90G has a second resonator structure. The second resonator structure can resonate and emphasize green light contained in white light emitted by the OLED layer 92. The second resonator structure includes the first electrode 21 and the second electrode 93. An optical path length between the first electrode 21 and the second electrode 93 in the light emitting element 90G may be set to a spectrum peak wavelength of the green subpixel 100G.

The light emitting element 90B is a blue OLED element. The light emitting element 90B includes the first electrode 21, the OLED layer 92, and the second electrode 93 sequentially on the first surface of the circuit board 11.

The light emitting element 90B has a third resonator structure. The third resonator structure can resonate and emphasize blue light included in white light emitted by the OLED layer 92. The third resonator structure includes the first electrode 21 and the second electrode 93. An optical path length between the first electrode 21 and the second electrode 93 in the light emitting element 90B may be set to a spectrum peak wavelength of the blue subpixel 100B.

In the display device 10j according to Modification 10, the light emitting element 90R, the light emitting element 90G, and the light emitting element 90B have the first resonator structure, the second resonator structure, and the third resonator structure, respectively, so that color purity of the display device 10j can be improved. Furthermore, front luminance can be improved.

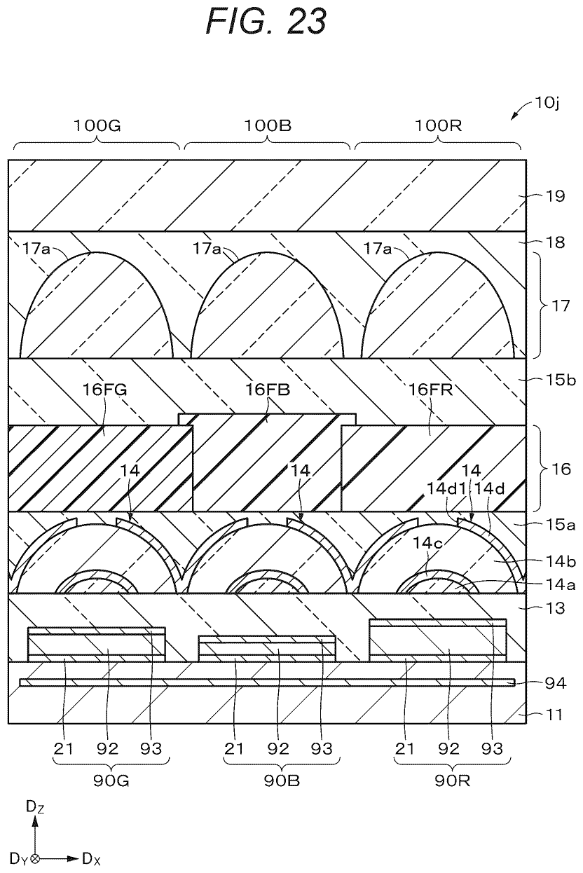

In the example described above, an example has been described in which the first electrode 21 is a reflective electrode having a function as a reflective layer, and the first electrode 21 and the second electrode 93 constitute the first to third resonator structures, but the configurations of the first to third resonator structures are not limited thereto. For example, as illustrated in FIG. 23, the display device 10j may include a reflective layer 94 provided below the first electrode 21, and the first to third resonator structures may be configured by the reflective layer 94 and the second electrode 93. In this case, the first electrode 21 is a transparent electrode. The reflective layer 94 has a planar shape perpendicular to a thickness direction of the light emitting element 20. The reflective layer 94 may be divided between adjacent subpixels 100, or may be connected between the adjacent subpixels 100. The reflective layer 94 is an example of a second reflective layer.

Furthermore, a distance between the reflective layer 94 and the second electrode 93 in the subpixels 100R, 100G, and 100B may be set according to a thickness of the OLED layer 92, or may be set according to a thickness of the insulating layer between the reflective layer 94 and the first electrode 21.

### <Modification 11>

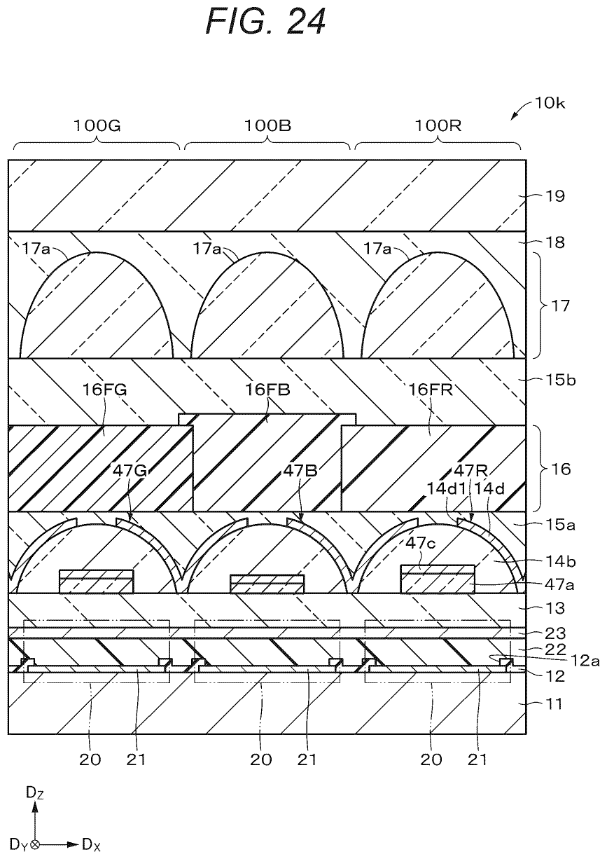

FIG. 24 is a cross-sectional view illustrating an example of a configuration of a display device 10k according to Modification 11. The display device 10k includes a plurality of reflective structures 47R, a plurality of reflective structures 47G, and a plurality of reflective structures 47B, instead of the plurality of reflective structures 14 (see FIG. 3). Although FIG. 24 illustrates an example in which the color filter 16 is provided, the color filter 16 may not be provided.

The reflective structures 47R, 47G, and 47B are included in the subpixels 100R, 100G, and 100B, respectively. The reflective structures 47R, 47G, and 47B include a structure 47a, a reflective layer 47c, the structure 14b, and the reflective layer 14d. The structure 47a has a flat upper surface. The structure 47a has, for example, a columnar shape. The columnar shape is, for example, a substantially columnar shape, a substantially elliptical columnar shape, or a substantially polygonal columnar shape. A height of the structure 47a is different for each of the reflective structures 47R, 47G, and 47B. An optical path length between the first electrode 21 and the reflective layer 47c is adjusted by the height of the structure 47a, for each of the subpixels 100R, 100G, and 100B. The reflective layer 47c has a planar shape.

The subpixel 100R has a first resonator structure. The first resonator structure can resonate and emphasize red light included in white light emitted by the OLED layer 22. The first resonator structure includes the first electrode 21 and the reflective layer 47c included in the subpixel 100R. An optical path length between the first electrode 21 and the reflective layer 47c in the subpixel 100R may be set to a spectrum peak wavelength of the red subpixel 100R.

The subpixel 100G has a second resonator structure. The second resonator structure can resonate and emphasize green light contained in white light emitted by the OLED layer 22. The second resonator structure includes the first electrode 21 and the reflective layer 47c included in the subpixel 100G. An optical path length between the first electrode 21 and the reflective layer 47c in the subpixel 100G may be set to a spectrum peak wavelength of the green subpixel 100G.

The subpixel 100B has a third resonator structure. The third resonator structure can resonate and emphasize blue light included in white light emitted by the OLED layer 22. The third resonator structure includes the first electrode 21 and the reflective layer 47c included in the subpixel 100B. An optical path length between the first electrode 21 and the reflective layer 47c in the subpixel 100B may be set to a spectrum peak wavelength of the blue subpixel 100R.

The reflective structures 47R, 47G, and 47B are similar to the reflective structure 14 of one embodiment in points other than the above.

In the display device 10k according to Modification 11, the subpixel 100R, the subpixel 100G, and the subpixel 100B have the first resonator structure, the second resonator structure, and the third resonator structure, respectively, so that color purity of the display device 10k can be improved. Furthermore, front luminance can be improved.

### <Modification 12>

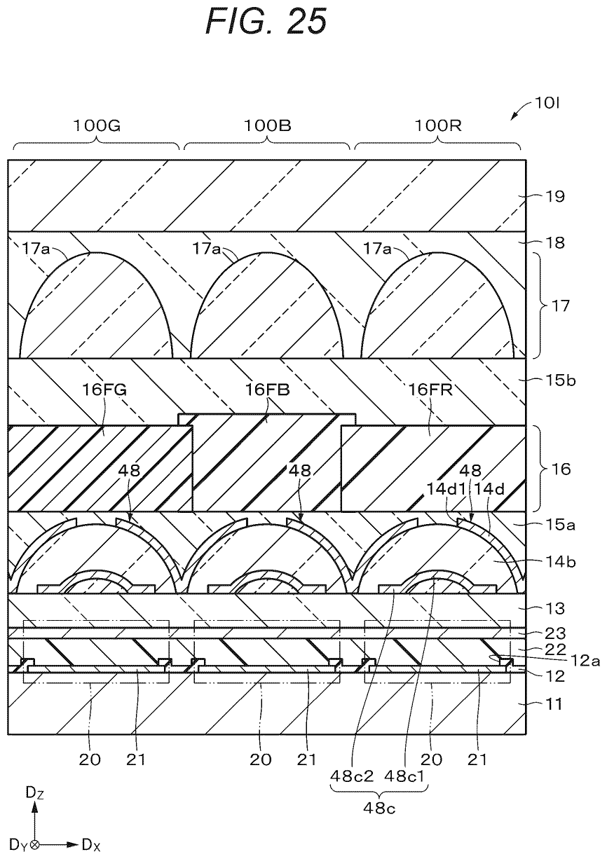

FIG. 25 is a cross-sectional view illustrating an example of a configuration of a display device 101 according to Modification 12. The display device 101 includes a plurality of reflective structures 48 instead of the plurality of reflective structures 14 (see FIG. 3).

The reflective structure 48 is different from the reflective structure 14 of one embodiment in that a reflective layer 48c is provided instead of the reflective layer 14c. The reflective layer 48c includes a convex portion 48c1 and a flat portion 48c2.

The convex portion 48c1 has a shape similar to that of the reflective layer 14c of the first embodiment. The flat portion 48c2 extends from a periphery of the convex portion 48c1 in an in-plane direction of the first surface of the protective layer 13. A peripheral edge of the flat portion 48c2 and a peripheral edge of the reflective layer 14d are separated from each other.

The display device 101 may include both the plurality of reflective structures 14 and the plurality of reflective structures 48.

### <Modification 13>

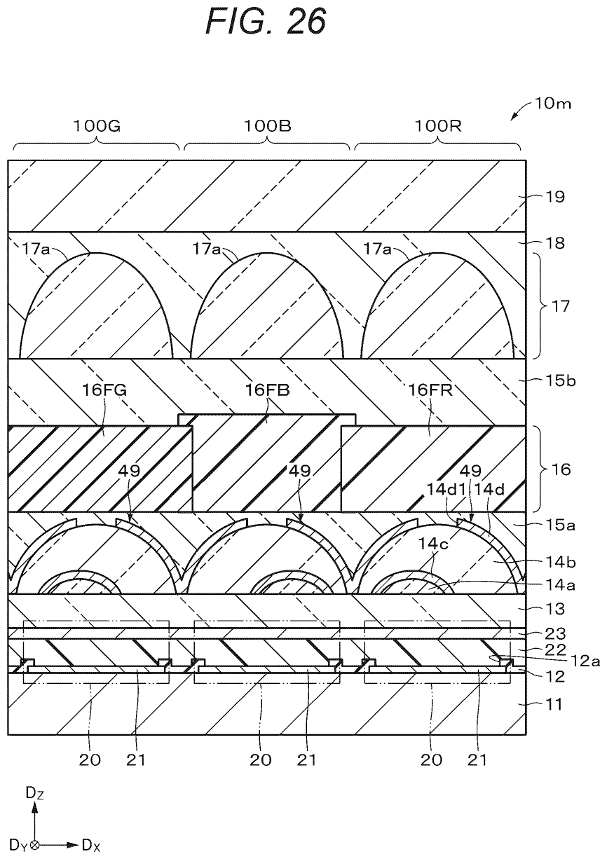

FIG. 26 is a cross-sectional view illustrating an example of a configuration of a display device 10m according to Modification 13. The display device 10m includes a plurality of reflective structures 49 instead of the plurality of reflective structures 14 (see FIG. 3).

The reflective structure 49 is different from the reflective structure 14 according to one embodiment in that center axes of the structure 14a and the structure 14b, that is, center axes of the reflective layer 14c and the reflective layer 14d are shifted in at least one of the horizontal direction D_{X} or the vertical direction D_{Y}.

The display device 10m may include both the reflective structure 14 in which the center axes of the structure 14a and the structure 14b coincide with each other and the reflective structure 49 in which the center axes of the structure 14a and the structure 14b are shifted from each other. That is, the display device 10m may include both the reflective structure 14 in which the center axes of the reflective layer 14c and the reflective layer 14d coincide with each other and the reflective structure 49 in which the center axes of the reflective layer 14c and the reflective layer 14d are shifted from each other.

The center axis of the structure 14a and the center axis of the first electrode 21 may be shifted in at least one of the horizontal direction D_{X} or the vertical direction D_{Y}. That is, the center axis of the reflective layer 14c and the center axis of the first electrode 21 may be shifted in at least one of the horizontal direction D_{X} or the vertical direction D_{Y}.

The center axis of the structure 14b and the center axis of the first electrode 21 may be shifted in at least one of the horizontal direction D_{X} or the vertical direction D_{Y}. That is, the center axis of the reflective layer 14d and the center axis of the first electrode 21 may be shifted in at least one of the horizontal direction D_{X} or the vertical direction D_{Y}.

### <Modification 14>

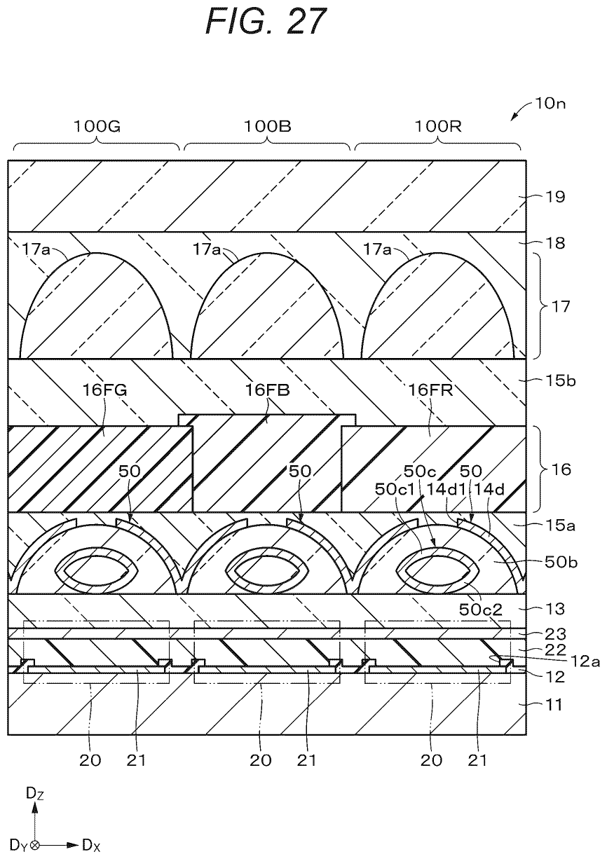

FIG. 27 is a cross-sectional view illustrating an example of a configuration of a display device 10n according to Modification 14. The display device 10n includes a plurality of reflective structures 50 instead of the plurality of reflective structures 14 (see FIG. 3).

The reflective structure 50 includes a structure 50b and the reflective layer 14d. The structure 50b has a convex surface protruding in a direction away from the light emitting element 20. As a shape of the convex surface, a shape similar to that of the structure 14b of one embodiment can be exemplified.

The structure 50b includes a reflector 50c therein. The reflector 50c is provided between the opening 14d1 of the reflective layer 14d and the light emitting element 20. A center axis of the reflector 50c preferably substantially coincides with the center axis of the reflective layer 14d. The reflector 50c has a biconvex surface structure. Specifically, the reflector 50c has a first convex curved surface protruding in a direction approaching the light emitting element 20 and a second concave curved surface protruding in a direction away from the light emitting element 20. The reflector 50c includes a reflective layer 50c1 and a reflective layer 50c2. The reflective layer 50c1 has a shape similar to that of the reflective layer 14c of one embodiment. The reflective layer 50c2 has a convex surface shape protruding in a direction approaching the light emitting element 20. The convex surface shape has, for example, a convex curved surface shape or a frustum surface shape. As the convex curved surface shape, a shape similar to the concave curved surface shape of the reflective layer 14c of one embodiment can be exemplified. As the frustum surface shape, a shape similar to the frustum surface shape of the reflective layer 14c of one embodiment can be exemplified.

The reflective layer 50c1 and the reflective layer 50c2 are provided such that the concave surfaces of the reflective layer 50c1 and the reflective layer 50c2 face each other, to constitute the reflective surface having the biconvex surface structure. FIG. 26 illustrates an example in which the reflective layer 50c1 and the reflective layer 50c2 are connected at a peripheral edge portion, but the reflective layer 50c1 and the reflective layer 50c2 may be divided. As a material of the reflective layers 50c1 and 50a2, a material similar to that of the reflective layer 14c of one embodiment can be exemplified.

In the display device 10n according to Modification 14, the reflective layer 50c2 provided above the light emitting element 20 has the convex surface protruding in the direction approaching the light emitting element 20. As a result, light output upward from the light emitting element 20 is reflected by the reflective layer 50c2 toward a peripheral edge portion of the first surface of the first electrode 21. Therefore, it is possible to prevent light from being confined between the first electrode 21 and the reflector 50c. Therefore, an amount of light extracted from the reflective structure 50 can be increased.

In the example described above, an example has been described in which the reflector 50c includes both the reflective layers 50c1 and 50c2, but the reflector 50c may include only the reflective layer 50c2.

### <Modification 15>

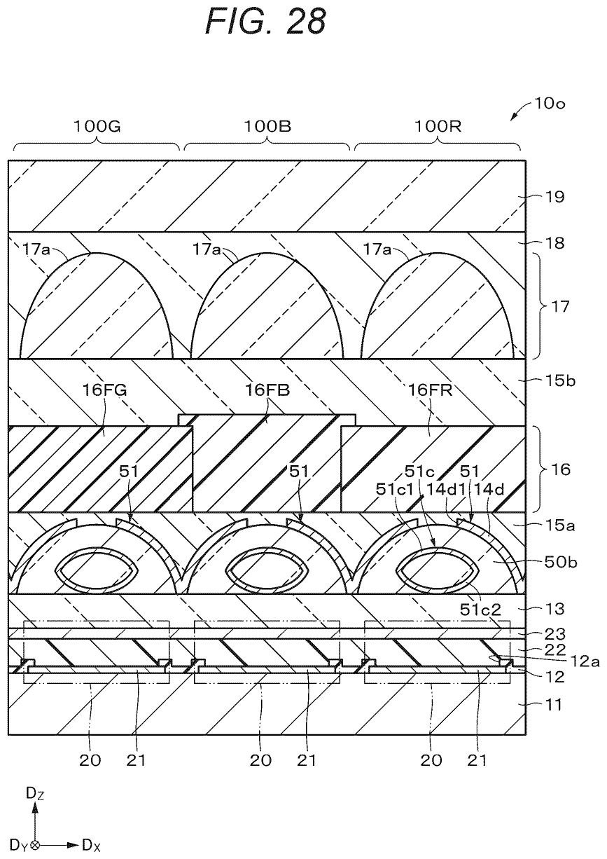

FIG. 28 is a cross-sectional view illustrating an example of a configuration of a display device 100 according to Modification 15. The display device 100 includes a plurality of reflective structures 51 instead of the plurality of reflective structures 14 (see FIG. 3).

The reflective structure 51 is similar to the reflective structure 50 of Modification 14 except that a semi-transmissive reflector 51c is provided instead of the reflector 50c. The semi-transmissive reflector 51c can transmit a part of light output upward from the light emitting element 20, and reflect the rest.

The semi-transmissive reflector 51c includes a semi-transmissive reflective layer 51c1 and a semi-transmissive reflective layer 51c2. The semi-transmissive reflective layers 51c1 and 51c2 can transmit a part of incident light and reflect the rest. As a material of the semi-transmissive reflective layers 51c1 and 51c2, a material similar to that of the metal layer of the second electrode 23 can be exemplified.

In the display device 100 according to Modification 15, a part of light output upward from the light emitting element 20 is reflected toward a peripheral edge portion of the first surface of the first electrode 21 by the semi-transmissive reflector 51c. Whereas, the rest of the light output upward from the light emitting element 20 is transmitted through the semi-transmissive reflector 51c, and output from the opening 14d1 of the reflective layer 14d. Therefore, it is possible to prevent light from being confined between the first electrode 21 and the semi-transmissive reflector 51c. Therefore, an amount of light extracted from the reflective structure 51 can be increased. In the example described above, the semi-transmissive reflector 51c includes both the semi-transmissive reflective layers 51c1 and 51c2, but the semi-transmissive reflector 51c may include any one of the semi-transmissive reflective layers 51c1 and 51c2.

### <Modification 16>

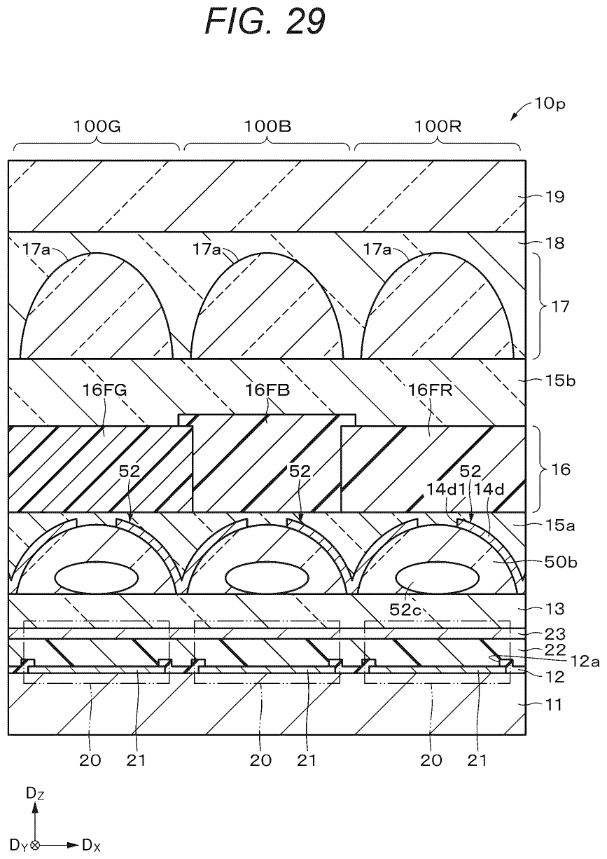

FIG. 29 is a cross-sectional view illustrating an example of a configuration of a display device 10p according to Modification 16. The display device 10p is different from the display device 10 according to one embodiment in including a plurality of reflective structures 52 instead of the plurality of reflective structures 14 (see FIG. 3).

The reflective structure 52 is similar to the reflective structure 50 of Modification 14 except that a reflector 52c is provided instead of the reflector 50c. The reflector 52c is a hollow portion. The hollow portion includes, for example, a gas such as air. The reflector 50c preferably has a convex surface protruding in a direction away from the light emitting element 20. The reflector 50c preferably has a convex surface protruding in a direction approaching the light emitting element 20. The reflector 50c may have a planar shape perpendicular to a thickness direction of the light emitting element 20.

In the example described above, an example in which the reflector 52c is hollow has been described, but the reflector 52c may contain a low refractive material having a refractive index lower than that of the material of the structure 50b. The low refractive material may be an organic material or an inorganic material.

### <Modification 17>

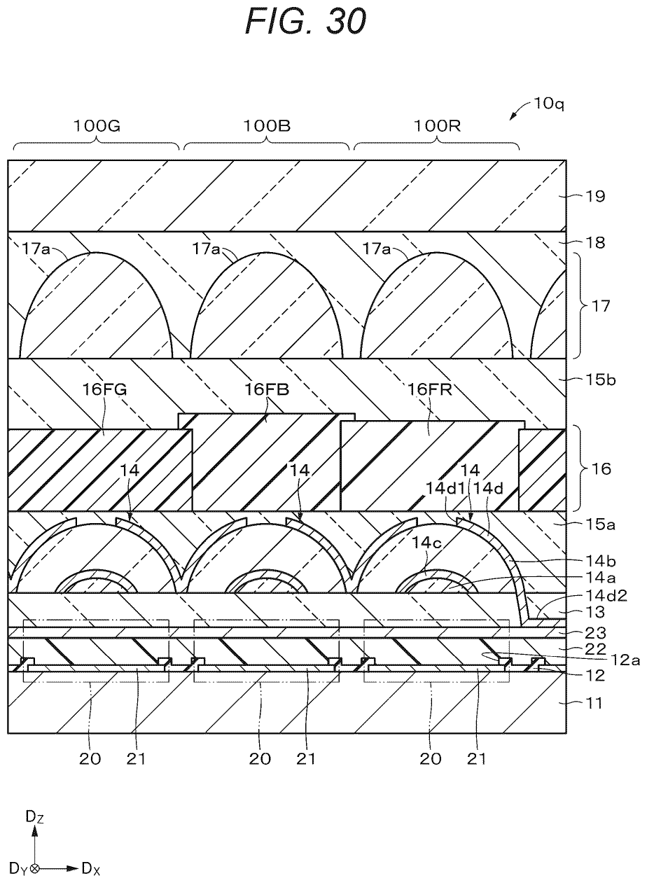

FIG. 30 is a cross-sectional view illustrating an example of a configuration of a display device 10q according to Modification 17. In the display device 10q, the reflective layer 14d has a plurality of connection portions 14d2 connected to the second surface of the second electrode 23.

The reflective layer 14d in Modification 17 has a function as an auxiliary electrode of the second electrode 23. The connection portion 14d2 is provided in the peripheral region R2. Furthermore, the connection portion 14d2 is provided at a prescribed position in the display region R1.

In the display device 10q according to Modification 17, the reflective layer 14d is connected to the second surface of the second electrode 23 by the plurality of connection portions 14d2. As a result, the reflective layer 14d can function as an auxiliary electrode of the second electrode 23. Therefore, a voltage drop in a central portion of the display region R1 can be suppressed.

### <Modification 18>

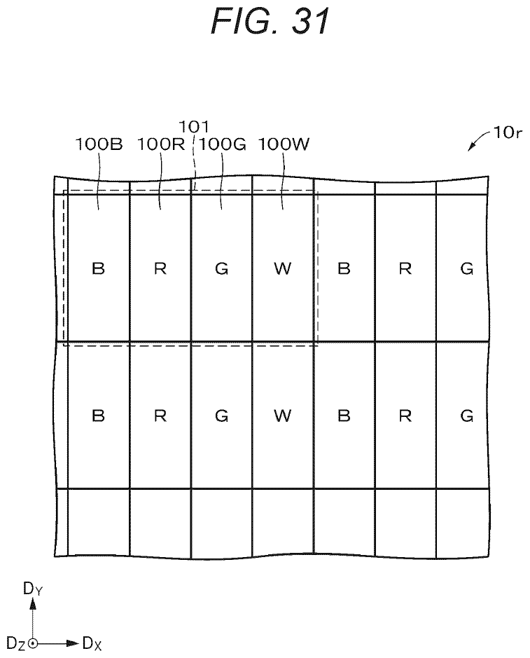

FIG. 31 is an enlarged plan view illustrating a part of the display region R1 of a display device 10r according to Modification 18. The display device 10r is different from the display device 10 according to one embodiment in further including a plurality of subpixels 100W. In Modification 18, one pixel 101 includes four subpixels 100R, 100G, 100B, and 100 W adjacent to each other in the horizontal direction D_{X}.

The subpixels 100W can emit white light. The color filter 16 has a plurality of openings. Each opening is provided at a position of the subpixel 100W. The subpixel 100W may or may not include the reflective structure 14.

In the display device 10r according to Modification 18, the one pixel 101 includes the four adjacent subpixels 100R, 100G, 100B, and 100W. As a result, luminance of the subpixels 100R, 100G, and 100B can be compensated by the white subpixel 100W.

### <Modification 19>

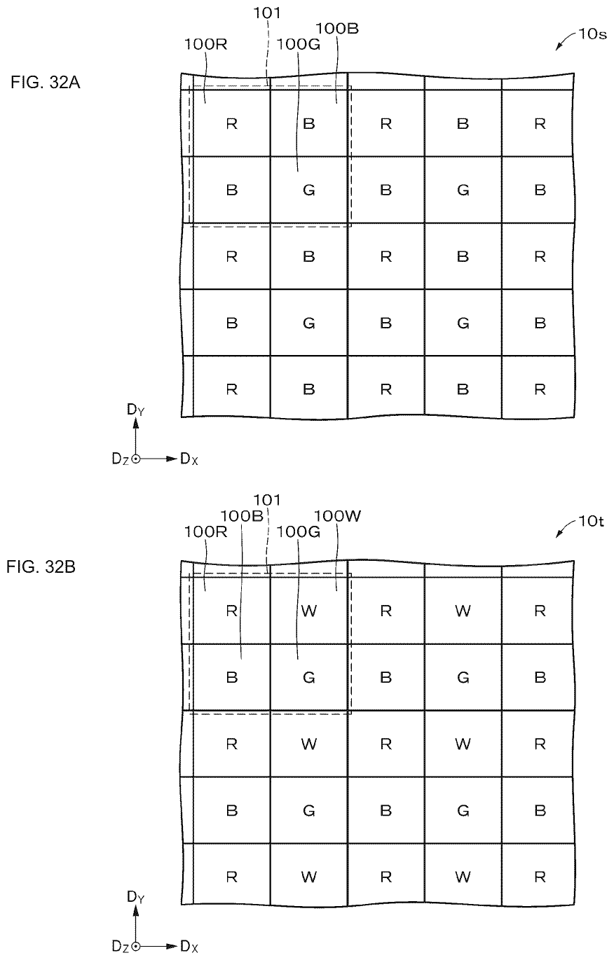

FIG. 32A is an enlarged plan view illustrating a part of the display region R1 of a display device 10s according to Modification 19. The display device 10s is different from the display device 10 according to one embodiment in that the one pixel 101 includes four subpixels 100R, 100G, 100B, and 100B arranged in a square shape. The subpixels 100R, 100G, and 100B each have a square shape. In the one pixel 101, the subpixel 100R and the subpixel 100G are adjacent to each other in an oblique direction. In the one pixel 101, the subpixel 100B and the subpixel 100B are adjacent to each other in an oblique direction.

### <Modification 20>

FIG. 32B is an enlarged plan view illustrating a part of the display region R1 of a display device 10t according to Modification 20. The display device 10t is different from the display device 10 according to one embodiment in that the one pixel 101 includes four subpixels 100R, 100G, 100B, and 100W arranged in a square shape. The subpixels 100R, 100G, 100B, and 100W each have a square shape. In the one pixel 101, the subpixel 100R and the subpixel 100G are adjacent to each other in an oblique direction. In the one pixel 101, the subpixel 100B and the subpixel 100W are adjacent to each other in an oblique direction.

### <Modification 21>

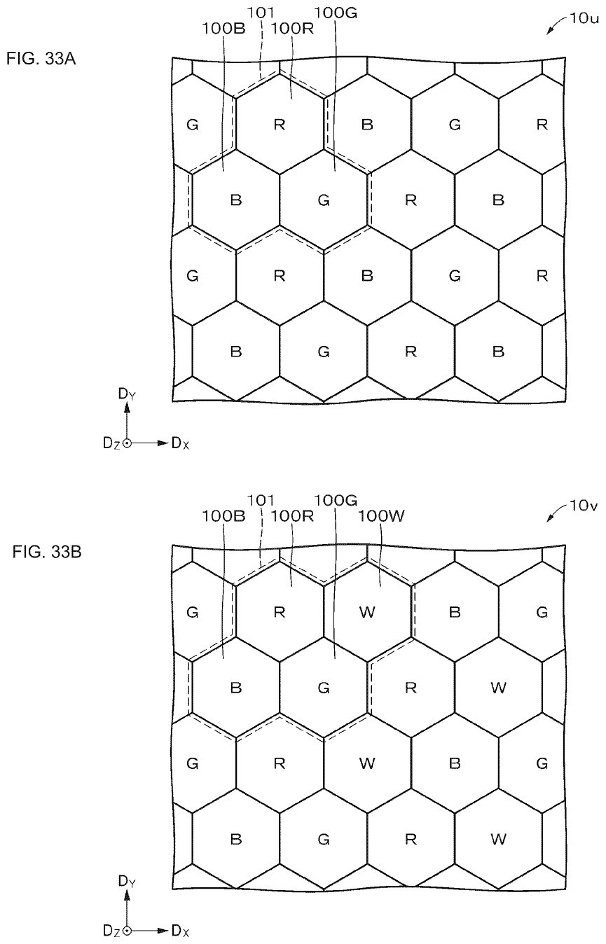

FIG. 33A is an enlarged plan view illustrating a part of the display region R1 of a display device 10u according to Modification 21. The display device 10u is different from the display device 10 according to one embodiment in that the one pixel 101 includes three subpixels 100R, 100G, and 100B arranged in a delta shape. The subpixels 100R, 100G, and 100B each have a hexagonal shape.

### <Modification 22>

FIG. 33B is an enlarged plan view illustrating a part of the display region R1 of a display device 10v according to Modification 22. The display device 10v is different from the display device 10u according to Modification 21 in that the subpixel 100W is further added to three subpixels 100R, 100G, and 100B arranged in a delta shape. The subpixel 100W has a hexagonal shape similarly to the subpixels 100R, 100G, and 100B.

### <Modification 23>

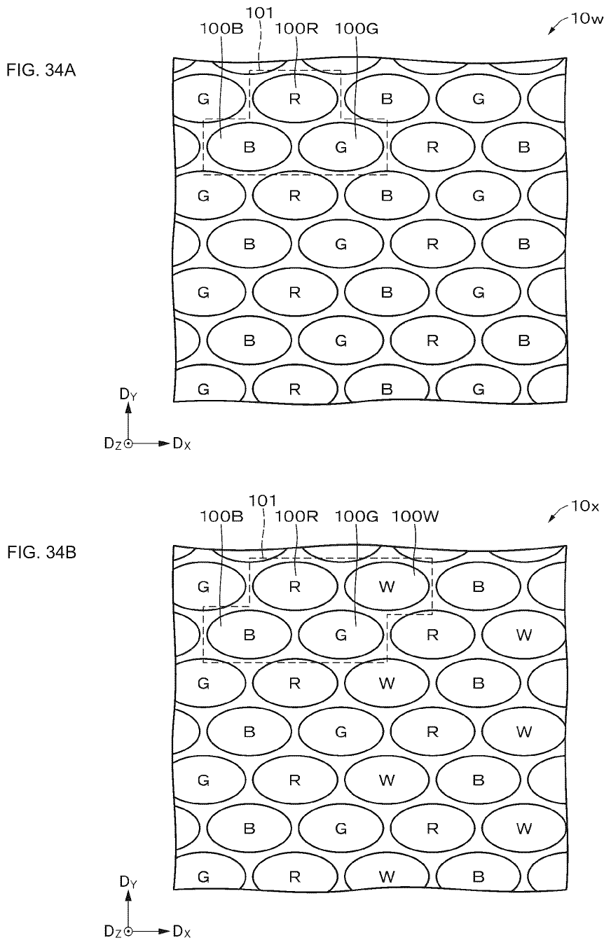

FIG. 34A is an enlarged plan view illustrating a part of the display region R1 of a display device 10w according to Modification 23. The display device 10w is different from the display device 10u according to Modification 21 in that the subpixels 100R, 100G, and 100B each have an elliptical shape. A long axis direction of the subpixels 100R, 100G, and 100B is, for example, parallel to the horizontal direction D_{X}.

### <Modification 24>

FIG. 34B is an enlarged plan view illustrating a part of the display region R1 of a display device 10x according to Modification 24. The display device 10x is different from the display device 10v according to Modification 22 in that the subpixels 100R, 100G, 100B, and 100W each have an elliptical shape. A long axis direction of the subpixels 100R, 100G, 100B, and 100W is, for example, parallel to the horizontal direction D_{X}.

### <Modification 25>

In one embodiment described above, a description has been given to the example (see FIGS. 6A and 6B) of forming the plurality of structures 14b by patterning the lens material layer 114b and then melting and curing the lens material layer 114b in the step of forming the structure 14b, but the method of forming the structure 14b is not limited thereto. For example, the plurality of structures 14b may be formed by forming an inorganic layer on the first surface of the protective layer 13 so as to follow the convex surface of the reflective layer 14c by using a film forming method such as a CVD method in which throwing power of an inorganic layer (uniformity of a thickness of the inorganic layer) is favorable.

In the method for manufacturing the display device 10 according to Modification 25, the structure 14b can be formed on the reflective layer 14c by self-alignment. Therefore, a positional misalignment between the center axes of the structure 14a and the structure 14b, that is, a positional misalignment between the center axes of the reflective layer 14c and the reflective layer 14d can be suppressed.

### <Other Modifications>

Although the above-described one embodiment of the present disclosure and Modifications 1 to 25 thereof have been specifically described, the present disclosure is not limited to the above-described embodiment and Modifications 1 to 25 thereof, and various modifications based on the technical idea of the present disclosure can be made.

For example, the configurations, methods, steps, shapes, materials, numerical values, and the like described in the above-described one embodiment and Modifications 1 to 25 thereof are merely examples, and different configurations, methods, steps, shapes, materials, numerical values, and the like may be used as necessary.

For example, the configurations, methods, steps, shapes, materials, numerical values, and the like of the above-described one embodiment and Modifications 1 to 25 thereof can be combined with each other without departing from the gist of the present disclosure.

For example, the materials exemplified in the above-described one embodiment and Modifications 1 to 25 thereof can be used alone or in combination of two or more unless otherwise specified.

Furthermore, the present disclosure may also employ the following configurations.

(1)

A display device including:
a plurality of light emitting elements arranged two-dimensionally; and
a plurality of reflective structures provided individually above a plurality of the light emitting elements, in which
each of the light emitting elements includes an organic layer including a light emitting layer, and
each of the reflective structures includes:
a first reflective layer having a concave shape concaved in a direction away from each of the light emitting elements and having an opening at a bottom portion of the concave shape; and
a reflector provided between the opening and each of the light emitting elements.
   (2)

The display device according to (1), in which
the reflector is a reflective layer having a convex curved surface shape protruding in a direction approaching each of the light emitting elements, a concave curved surface shape concaved in a direction away from each of the light emitting elements, or a planar shape perpendicular to a thickness direction of each of the light emitting elements.
   (3)

The display device according to (1), in which
the reflector has a first convex curved surface protruding in a direction approaching each of the light emitting elements and a second convex curved surface protruding in a direction away from each of the light emitting elements.
   (4)

The display device according to any one of (1) to (3), in which
the concave shape is a concave curved surface shape.
   (5)

The display device according to any one of (1) to (4), in which
the reflector is a semi-transmissive reflective layer.
   (6)

The display device according to any one of (1) to (4), in which
the reflector is hollow.
   (7)

The display device according to any one of (1) to (6), in which
each of the light emitting elements further includes a second reflective layer, and
the organic layer is provided on the second reflective layer or above the second reflective layer.
   (8)

The display device according to (7), in which
the first reflective layer and the second reflective layer are electrodes.
   (9)

The display device according to any one of (1) to (6), in which
each of the light emitting elements further includes:
a second reflective layer; and
a transparent electrode provided on the second reflective layer or above the second reflective layer.
   (10)

The display device according to any one of (7) to (9), in which
the second reflective layer has a planar shape perpendicular to a thickness direction of each of the light emitting elements or a curved shape concaved in a direction away from each of the light emitting elements.
   (11)

The display device according to any one of (1) to (10), in which
a ratio of a size of the opening of the first reflective layer to a size of the reflector is 30% or more and 80% or less.
   (12)

The display device according to any one of (1) to (11), in which
a reflective structure included in a plurality of the reflective structures is the reflective structure in which a center axis of the reflector is shifted from a center axis of the first reflective layer.
   (13)

The display device according to any one of (1) to (12), in which
the organic layer is connected between adjacent light emitting elements among the light emitting elements.
   (14)

The display device according to any one of (1) to (13), in which
each of the light emitting elements has a resonator structure.
   (15)

The display device according to any one of (1) to (14), further including:
a partition wall provided between adjacent light emitting elements among the light emitting elements.
   (16)

The display device according to any one of (1) to (14), in which
a gap is provided between adjacent light emitting elements among the light emitting elements.
   (17)

The display device according to any one of (1) to (16), in which
each of the light emitting elements has a collimator structure.
   (18)

The display device according to any one of (1) to (17), further including:
a color filter provided above a plurality of the reflective structures.
   (19)

The display device according to any one of (1) to (18), further including:
a lens array provided above a plurality of the reflective structures.
   (20)

An electronic device including the display device according to any one of (1) to (19).

### 3 Application Example

### (Electronic Device)

The display devices 10, 10a to 10x (hereinafter, referred to as a “display device 10 and the like”) according to the above-described one embodiment and Modifications 1 to 25 thereof can be provided in various electronic devices. The display device 10 and the like are suitable especially for an electronic view finder of a video camera or a single-lens reflex camera, a head-mounted display, or the like requiring high resolution and used near the eyes in an enlarged manner.

### First Specific Example

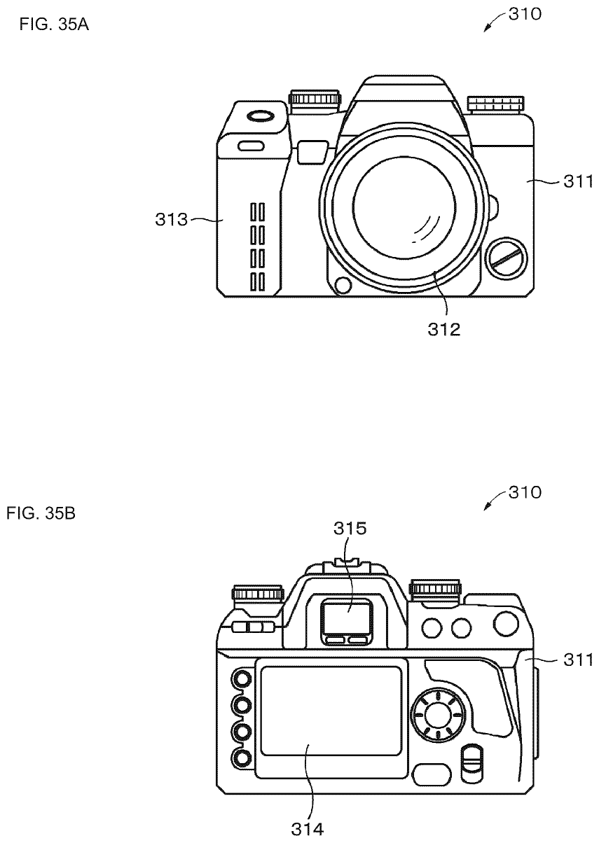

FIGS. 35A and 35B illustrate an example of an appearance of a digital still camera 310. The digital still camera 310 is of a lens interchangeable single-lens reflex type, and includes an interchangeable imaging lens unit (interchangeable lens) 312 substantially at the center on a front surface of a camera main body (camera body) 311, and a grip 313 to be held by a photographer on a front left side.

A monitor 314 is provided at a position shifted to the left side from the center of a rear surface of the camera main body 311. An electronic view finder (eyepiece window) 315 is provided above the monitor 314. By looking through the electronic view finder 315, the photographer can visually confirm an optical image of a subject guided from the imaging lens unit 312 and determine a picture composition. The electronic view finder 315 includes any one of the display device 10 and the like described above.

### Second Specific Example

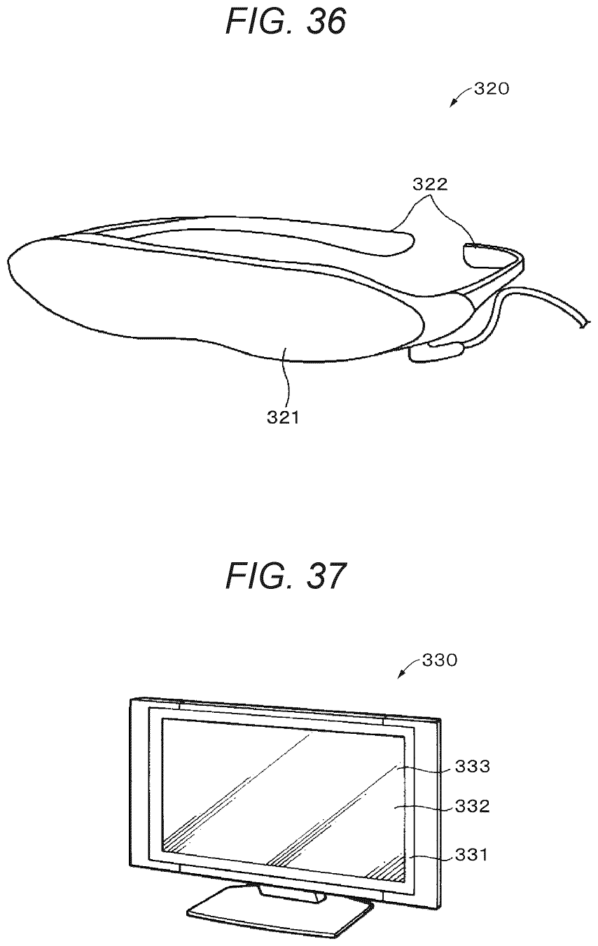

FIG. 36 illustrates an example of an appearance of a head mounted display 320. The head mounted display 320 includes, for example, ear hooking portions 322 to be worn on the head of the user on both sides of a glass-shaped display unit 321. The display unit 321 includes any one of the above-described display devices 10 and the like.

### Third Specific Example

FIG. 37 illustrates an example of an appearance of a television device 330. The television device 330 includes, for example, a video display screen unit 331 including a front panel 332 and a filter glass 333, and the video display screen unit 331 includes any one of the display device 10 described above and the like.

### REFERENCE SIGNS LIST

10, 10a, 10b, 10c, 10d, 10e, 10f, 10g, 10 h, 10i, 10j, 10k, 10s,
10t, 10u, 10v, 10w, 10x Display device
11 Circuit board
11a Pad
12 Insulating layer
12a Opening
13 Protective layer
14 Reflective structure
14a Structure
14b Structure
14c Reflective layer
14d Reflective layer
14d1 Opening
14d2 Connection portion
15a, 15b Planarization layer
16 Color filter
16FR Red filter portion
16FG Green filter portion
16FB Blue filter portion
17 Lens array
17a Lens
18 Filling resin layer
19 Counter substrate
20 Light emitting element
21 First electrode
22 OLED layer
23 Second electrode
31, 32 Resist layer
31a, 32a Opening
41 Reflective structure
41b Structure
41b1 Hole portion
42 Reflective structure
42a Reflective layer
43 Circuit board
43a Concave portion
44 Circuit board
44a Reflective layer
44s Curved surface
45 Partition wall
46 Gap
47R, 47G, 47B Reflective structure
47a Structure
47c Reflective layer
48 Reflective structure
48c Reflective layer
48c1 Convex portion
48c2 Flat portion
49 Reflective structure
50 Reflective structure
50b Structure
50c Reflector
50c1 Reflective layer
50c2 Reflective layer
51 Reflective structure
51c Semi-transmissive reflector
51c1 Semi-transmissive reflective layer
51c2 Semi-transmissive reflective layer
52 Reflective structure
52c Reflector
60 Light emitting element
61 First electrode
70 Light emitting element
72 OLED layer
72a Collimator structure
80R, 80G, 80B Light emitting element
82R, 82G, 82B OLED layer
83 Second electrode
90R, 90G, 90B Light emitting element
92 OLED layer
93 Second electrode
94 Reflective layer
100R, 100G, 100B, 100W Subpixel
114a, 114a1 Lens material layer
114b Lens material layer
141b Lens material layer
310 Digital still camera (electronic device)
320 Head mounted display (electronic device)
330 Television device (electronic device)
D_{X} Horizontal direction
D_{Y} Vertical direction
D_{Z} Front direction
R1 Display region
R2 Peripheral region

1. A display device comprising:
a plurality of light emitting elements arranged two-dimensionally; and
a plurality of reflective structures provided individually above a plurality of the light emitting elements, wherein
each of the light emitting elements includes an organic layer including a light emitting layer, and
each of the reflective structures includes:
a first reflective layer having a concave shape concaved in a direction away from each of the light emitting elements and having an opening at a bottom portion of the concave shape; and
a reflector provided between the opening and each of the light emitting elements.

2. The display device according to claim 1, wherein
the reflector includes a reflective layer having a convex curved surface shape protruding in a direction approaching each of the light emitting elements, a concave curved surface shape concaved in a direction away from each of the light emitting elements, or a planar shape perpendicular to a thickness direction of each of the light emitting elements.

3. The display device according to claim 1, wherein
the reflector has a first convex curved surface protruding in a direction approaching each of the light emitting elements and a second convex curved surface protruding in a direction away from each of the light emitting elements.

4. The display device according to claim 1, wherein
the concave shape is a concave curved surface shape.

5. The display device according to claim 1, wherein
the reflector includes a semi-transmissive reflective layer.

6. The display device according to claim 1, wherein
the reflector is hollow.

7. The display device according to claim 1, wherein
each of the light emitting elements further includes a second reflective layer, and
the organic layer is provided on the second reflective layer or above the second reflective layer.

8. The display device according to claim 7, wherein
the first reflective layer and the second reflective layer include electrodes.

9. The display device according to claim 1, wherein
each of the light emitting elements further includes:
a second reflective layer; and
a transparent electrode provided on the second reflective layer or above the second reflective layer.

10. The display device according to claim 7, wherein
the second reflective layer has a planar shape perpendicular to a thickness direction of each of the light emitting elements or a curved shape concaved in a direction away from each of the light emitting elements.

11. The display device according to claim 1, wherein
a ratio of a size of the opening of the first reflective layer to a size of the reflector is 30% or more and 80% or less.

12. The display device according to claim 1, wherein
a reflective structure included in a plurality of the reflective structures is the reflective structure in which a center axis of the reflector is shifted from a center axis of the first reflective layer.

13. The display device according to claim 1, wherein
the organic layer is connected between adjacent light emitting elements among the light emitting elements.

14. The display device according to claim 1, wherein
each of the light emitting elements has a resonator structure.

15. The display device according to claim 1, further comprising:
a partition wall provided between adjacent light emitting elements among the light emitting elements.

16. The display device according to claim 1, wherein
a gap is provided between adjacent light emitting elements among the light emitting elements.

17. The display device according to claim 1, wherein
each of the light emitting elements has a collimator structure.

18. The display device according to claim 1, further comprising:
a color filter provided above a plurality of the reflective structures.

19. The display device according to claim 1, further comprising:
a lens array provided above a plurality of the reflective structures.

20. An electronic device comprising the display device according to claim 1.
